(19) United States
(12) Patent Application Publication
(10) Pub. No.: US 2004/0137161 A1
(43) Pub. Date: Jul. 15, 2004

(54) Device and method for electroless plating

(76) Inventors: Yuji Segawa, Tokyo (JP); Shuzo Sato, Kanagawa (JP); Zenya Yasuda, Kanagawa (JP); Masao Ishihara, Tokyo (JP); Takeshi Nogami, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/474,020

(22) PCT Filed: Apr. 4, 2002
(86) PCT No.: PCT/JP02/03378

(30) Foreign Application Priority Data
Apr. 6, 2001 (JP) 2001-109156

(51) Int. Cl. H05K 3/00; C25D 5/02; B05B 7/06

(52) U.S. Cl. 427/430.1; 438/678; 205/126; 118/313

(57) ABSTRACT

An electroless plating apparatus controlling the changes in the plating solution along with the elapse of time for performing electroless plating uniformly with a good accuracy and a method thereof are provided. An electroless plating apparatus for applying electroless treatment to a target surface under an atmosphere of a predetermined gas so as to form a conductive film, has a plating tank 21 set so that a target surface of a target object W is close to its inside surface and isolating the target surface from the outside atmosphere, and a plating solution feeding means 26 for feeding a plating solution to the target surface so as to ease the impact of the plating solution on the target surface of the target object W.

### TECHNICAL FIELD

The present invention relates to an electroless plating apparatus and a method of the same, more particularly relates to an electroless plating apparatus for forming a conductive layer having a barrier property and a method of the same.

### BACKGROUND ART

In the past, as a material for the micro interconnects of a semiconductor chip comprised of a semiconductor wafer and an integrated circuit formed on it to a high density, aluminum or alloys of the same have been widely used.

However, to further raise the operating speed of a semiconductor chip, it is necessary to use copper, silver, or another material with a lower specific resistance as the material of the interconnects.

In particular, copper has a specific resistance of a low 1.8 μΩ·cm and therefore is advantageous for increasing the speed of a semiconductor chip. On top of this, it is about one order higher in electromigration resistance compared with an aluminum-based alloy. Therefore, it is gathering attention as a next-generation material.

However, copper has the property of easily diffusing in silicon or another insulating material and being fast in diffusion rate as well. Therefore, when using copper as an interconnect material, normally this problem is dealt with by forming a barrier metal layer for preventing diffusion of the copper at the interface of the copper with the insulating material.

The material used as the barrier metal layer includes for example tantalum, tantalum nitride, titanium, titanium nitride, tungsten, tungsten nitride, etc.

The above barrier metal layer has conventionally been formed by sputtering or another PVD (physical vapor deposition) method or a CVD (chemical vapor deposition) method etc.

However, as semiconductor chips have been made smaller and higher in integration, the interconnect rule has similarly been reduced to less than 0.13 μm. Further, as semiconductor devices have become greater in height, the silicon oxide and other interlayer insulating films covering these devices have tended to become thicker. Despite this, the open areas of the connection holes (trenches, contact holes, or via holes for electrically connecting devices or multilayer interconnects) have conversely become smaller. Therefore the aspect ratios of connection holes have become high aspect ratios of 5 or more. Under such circumstances, if forming the barrier metal layer by a PVD method or a CVD method, the coverage became poor and it becomes extremely difficult to uniformly form a film on the wall surfaces of the connect holes as well.

To solve the above problem, U.S. Pat. No. 5,695,810 discloses technology for forming a CoWP layer for forming the barrier metal layer by electroless plating.

Further, Japanese Unexamined Patent Publication (Kokai) No. 8-83796 discloses technology for forming a film of cobalt, nickel, etc. by electroless plating.

However, in the above methods, the electroless plating for depositing a CoWP layer is performed by an dipping system. Co(OH)₂ easily precipitates in the electroless plating reagent to thereby shorten the life of the electroless plating reagent. Further, there was the defect that, along with the elapse of time, a difference ended up appearing in the film-forming rates of the plating reagent at the start of the life and the plating reagent at the end.

If therefore preparing fresh electroless plating reagent as each electroless plating reagent deteriorated due to the short life, the amount used would end up increasing, there would be much trouble in production, and the production cost would rise—making commercial application difficult.

Further, in semiconductor applications, sodium hydroxide, which contains alkali metal ions, cannot be used for adjusting the pH, so ammonia is used for adjusting the pH. This ammonia easily evaporates, so becomes a cause of a shorter life.

Further, even if adding ammonium tungstate or ammonium molybdate into the electroless plating reagent to raise the barrier property of the barrier metal layer formed, due to evaporation of the ammonia, the tungstic acid or molybdic acid ended up precipitating, so there was the defect of a shorter life.

Further, in view of the above issues, it is necessary to achieve formation of a film with a uniform thickness in the wafer plane in the formation of a barrier metal.

### DISCLOSURE OF THE INVENTION

The present invention was made in consideration of the above situation and has as its object to provide an electroless plating apparatus controlling the changes in the plating solution along with the elapse in time so as to perform electroless plating uniformly with a good accuracy and a method of the same.

To achieve the above object, an electroless plating apparatus of the present invention is an electroless plating apparatus for electroless plating of a target surface in an atmosphere of a predetermined gas to form a conductive film, having a plating tank set so that the target surface of a target object is close to its inside surface and isolating the target surface from an outside atmosphere and a plating solution feeding means for feeding the plating solution to the target surface so as to ease impact of the plating solution to the target surface of the target object.

Further, to achieve the above object, an electroless plating apparatus of the present invention is an electroless plating apparatus for electroless plating of a target surface to form a conductive film, having a plating tank for holding a plating solution under an atmosphere of a predetermined gas and a holding member provided with a holding surface for holding the target object, having a clamping hole for suction clamping the target object to the holding surface, and having a groove formed with a blowing hole for blowing out the predetermined gas at an outer periphery of the holding surface and dipping the target object held by the holding member in the plating tank for electroless plating.

Further, to achieve the above object, an electroless plating apparatus of the present invention is an electroless plating apparatus for electroless plating of a target surface of a target object to form a conductive film, having a plating tank filled with a plating solution, a plating chamber holding the plating tank, and a gas feeding means for feeding a predetermined gas to the inside of the plating chamber.

Further, to achieve the above object, an electroless plating method of the present invention is an electroless plating method for electroless plating of a target surface in an atmosphere of a predetermined gas to form a conductive film, comprising setting a plating tank so that the target surface of a target object is isolated from an outside atmosphere and making the inside of the plating tank an atmosphere of a predetermined gas and feeding a plating solution to the target surface so as to ease impact of the plating solution to the target surface of the target object and performing electroless plating.

Further, to achieve the above object, an electroless plating method of the present invention is an electroless plating method dipping a target object in a plating tank holding a plating solution for electroless plating of a target surface of the target object to form a conductive film, comprising placing the target object on a holding surface of a holding member, blowing out a predetermined gas from an outer periphery of the holding surface, and in that state holding the target object by suction clamping at the holding surface and dipping the target object held by the holding member in the plating tank set to an atmosphere of a predetermined gas so that the target surface is close to an inside surface of the plating tank.

### BRIEF DESCRIPTION OF THE DRAWINGS

FIG. 1 is a schematic view of the configuration of an electroless plating apparatus according to a first embodiment.

FIG. 2 is a schematic view of the configuration of the electroless plating apparatus according to the first embodiment at the time of plating.

FIG. 3 is a sectional view of a semiconductor chip formed with a conductive film by the electroless plating apparatus of the present invention.

FIG. 4A to FIG. 4G are sectional views of steps in the case of forming a barrier metal in a semiconductor chip by the electroless plating apparatus of the present invention.

FIG. 5 is a view of the results of measurement of the thickness of a conductive film formed along with the reaction time of electroless plating.

FIG. 6 is a sectional view for explaining a step of selective formation of a barrier metal only on an interconnect use conductive film of the semiconductor chip shown in FIG. 3.

FIG. 7 is a view of the results of measurement of uniformity of thickness of a conductive film in a wafer plane in the case of feeding a plating solution to a wafer surface after bringing the plating solution into contact once with the top surface of an agitator and in a case of feeding an electroless plating solution directly to the wafer.

FIG. 8 is a schematic view of the configuration of an electroless plating apparatus according to a second embodiment.

FIG. 9 is a schematic view of the configuration of an electroless plating apparatus according to a third embodiment.

FIG. 10A and FIG. 10B are schematic views of the configuration of an electroless plating apparatus according to a fourth embodiment.

FIG. 11 is a schematic view of the configuration of an electroless plating apparatus according to a fifth embodiment.

FIG. 12 is a schematic view of the configuration of an electroless plating apparatus according to a sixth embodiment.

FIG. 13 is a schematic view of the configuration of an electroless plating apparatus according to a seventh embodiment.

FIG. 14 is a schematic view of the configuration of an electroless plating apparatus according to an eighth embodiment.

FIG. 15A to FIG. 15C are views of the configuration of an electroless plating apparatus according to a ninth embodiment.

FIG. 16A and FIG. 16B are views of the configuration of an electroless plating apparatus according to a 10th embodiment.

FIG. 17A and FIG. 17B are views of the configuration of an electroless plating apparatus according to an 11th embodiment.

FIG. 18A and FIG. 18B are views of the configuration of an electroless plating apparatus according to a 12th embodiment.

FIG. 19A and FIG. 19B are views of the configuration of an electroless plating apparatus according to a 13th embodiment.

FIG. 20 is a view of the configuration of an edge of a spin table of an electroless plating apparatus according to a 14th embodiment.

FIG. 21 is a view of the configuration of an edge of a spin table of an electroless plating apparatus according to a 15th embodiment.

FIG. 22 is a view of the configuration of an edge of a spin table of an electroless plating apparatus according to a 16th embodiment.

FIG. 23A and FIG. 23B are a plan view and a sectional view of a spin table used in an electroless plating apparatus according to a 17th embodiment.

FIG. 24 is a plan view of a spin table used in an electroless plating apparatus according to an 18th embodiment.

FIG. 25 is a plan view of a spin table used in an electroless plating apparatus according to a 19th embodiment.

FIG. 26A and FIG. 26B are a plan view and a sectional view of a spin table used in an electroless plating apparatus according to a 20th embodiment.

FIG. 27 is a plan view of a spin table used in an electroless plating apparatus according to a 21st embodiment.

FIG. 28A to FIG. 28E are plan views and sectional views of a spin table used in an electroless plating apparatus according to a 22nd embodiment.

FIG. 29A to FIG. 29E are plan views and sectional views of a spin table used in an electroless plating apparatus according to a 23rd embodiment.

FIG. 30A to FIG. 30E are plan views and sectional views of a spin table used in an electroless plating apparatus according to a 24th embodiment.

FIG. 31A to FIG. 31E are plan views and sectional views of a spin table used in an electroless plating apparatus according to a 25th embodiment.

### BEST MODE FOR CARRYING OUT THE INVENTION

### First Embodiment

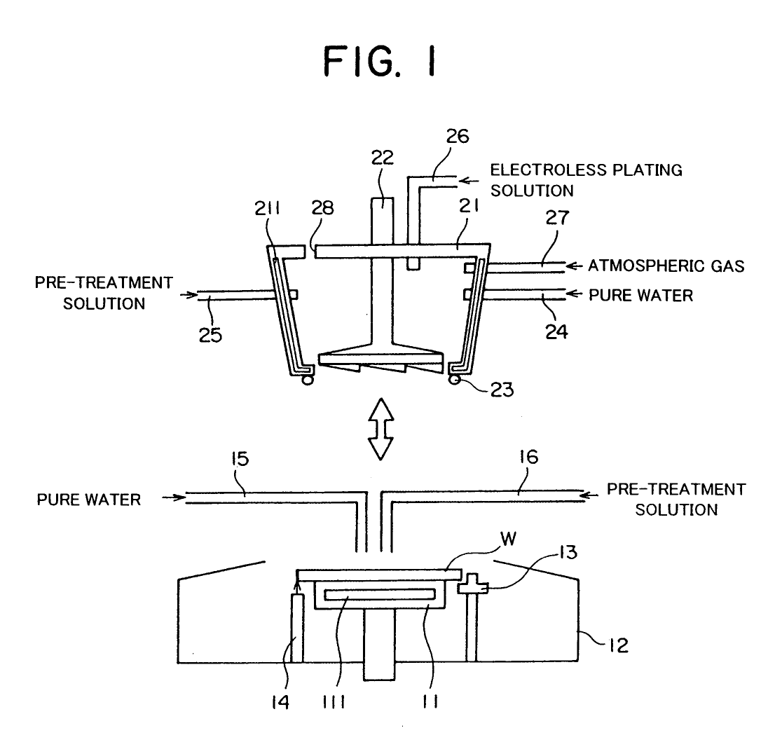

FIG. 1 is a schematic view of the configuration of an electroless plating apparatus according to the present embodiment.

The electroless plating apparatus according to the present embodiment has a spin table 11 able to spin while holding a semiconductor wafer W, a heater 111 embedded in the spin table 11, an outside tank 12 housing excess solution overflowing from the wafer W, a pipe 14 for feeding a washing solution for washing a back surface of the wafer W from a not shown tank, and a scrub member 13 for scrubbing the back surface of the wafer.

The spin table 11 is provided with a large number of clamping holes for suction clamping the wafer W at its holding surface. Through spin coating or puddling, the target surface of the wafer W can be washed, pre-treated, and otherwise treated. As the treatment solution feeding system for this, pipes 15 and 16 for feeding pure water, a pre-treatment solution, or another reagent on the wafer W from a not shown tank are provided movably above the spin table 11.

A plating cup 21 is set above the spin table 11 movable in a direction facing the spin table 11.

The plating cup 21 is provided with a heater 211 embedded in the plating cup 21, an agitator 22, pipes 24, 25, 26, and 27 for feeding pure water, pre-treatment solution, electroless plating solution, inert gas, nitrogen gas, ammonia gas, or other atmospheric gas into the plating cup 21 from a not shown tank or pressure tank, an exhaust port 28 for exhausting the atmospheric gas in the plating cup 21, a seal member 23 for sealing the contact parts of the plating cup 21 and wafer W when the plating cup 21 and spin table 11 are mated, etc.

The electroless plating solution feed pipe 26 is provided at the top surface of the plating cup 21 and is designed to feed plating solution to the wafer W after bringing the plating solution into contact once with the agitator 22.

The agitator 22 has an agitation part of for example a circular shape whose top surface is inclined downward from the center toward the outsides. Further, the bottom surface has projections, recesses, or other step differences for agitation use.

The operation when plating a wafer W using the above electroless plating apparatus will be explained next.

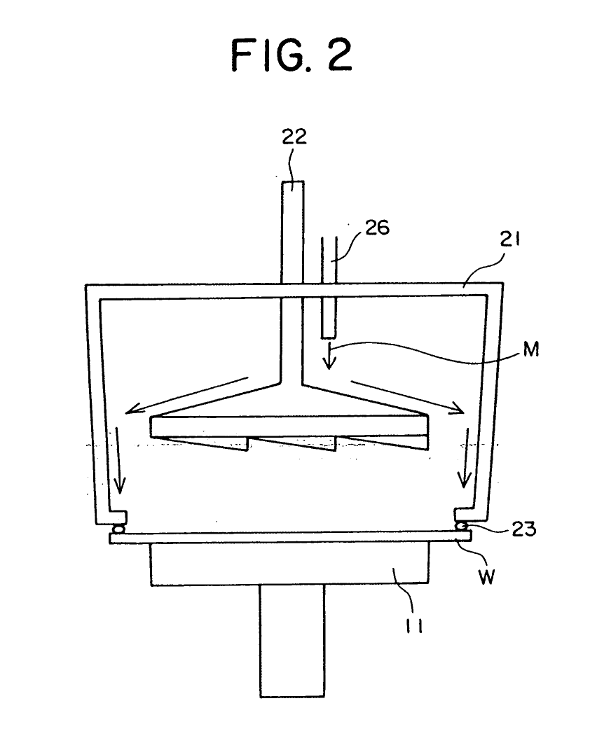

First, from the state with the plating cup 21 and spin table 11 separated as shown in FIG. 1, the plating cup 21 is made to move downward using a motor etc. or the spin table 11 is driven upward using a motor etc. so as to seal the contact parts of the plating cup 21 and the wafer W by the seal member 23 and mate the plating cup 21 and spin table 11 and thereby isolate the target surface of the wafer W from the outside atmosphere as shown in FIG. 2.

Further, in the state with the wafer W held on the spin table 11 shown in FIG. 2, for example nitrogen is filled into the plating cup 21 from a not shown pressure tank through a gas feed pipe 27. At this time, due to the exhaust port 28, the gas in the plating cup 21 is exhausted while the plating cup 21 is filled with nitrogen. Further, by making the nitrogen a similar temperature to the plating solution, there is also a warming effect on the plating solution.

Next, after the plating cup 21 is sufficiently filled with nitrogen, the electroless plating solution M is fed from a not shown tank through the electroless plating solution feed pipe 26 to the top surface of the agitator 22 while making the agitator 22 turn. The electroless plating solution M covering the top surface of the agitator further strikes the inside walls of the plating cup 21, travels along the inside walls of the plating cup 21, and collects on the wafer W. By making the electroless plating solution M strike the top surface of the agitator 22 once at this time, it is possible to prevent impact due to the plating solution falling from the electroless plating feed pipe 26 to the wafer W surface.

Further, the heaters 111 and 211 embedded in the spin table 11 and the plating cup 21 are actuated to heat the wafer W and the nitrogen in the plating cup 21 to predetermined temperatures.

Due to this, electroless plating is performed. By the agitating action of the plating solution by the agitator 22 and the temperature adjustment by the heaters 111 and 211, a uniform plating is formed on the wafer W.

After the plating is ended, as shown in FIG. 1, for example the spin table 11 is made to descend and the plating solution in the plating cup 21 is drained to the outside tank 12. At this time, while not shown, it is preferable to provide a movable shutter between the plating cup 21 and the semiconductor wafer W to separate the two and thereby prevent the solution from dripping from the plating cup 21 to the semiconductor wafer W.

By making the spin table 11 spin in this state, the plating solution deposited on the surface of the wafer W is spun off due to centrifugal force. Next, pure water is sprayed from a not shown tank through the pipe 15 to the surface of the wafer W to wash it.

A method of producing a barrier metal of a semiconductor chip by the above electroless plating apparatus will be explained next.

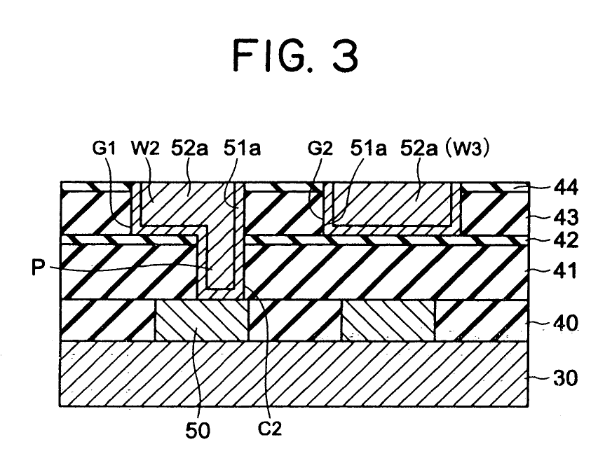

FIG. 3 is a sectional view of a semiconductor chip formed with a barrier metal or other conductive film by the electroless plating apparatus according to the present embodiment.

A semiconductor substrate 30 formed with an MOS transistor or other semiconductor device is formed with a first insulating film 40 comprised of for example silicon oxide. The first insulating film 40 is formed with an opening reaching the semiconductor substrate 30 and is formed with a first interconnect 50 comprised of copper, polycrystalline silicon, tungsten, or another conductive material.

Above the first insulating film 40 and the first interconnect 50, a second insulating film 41 comprised of for example silicon oxide, a first etching stopper 42 comprised of silicon nitride, a third insulating film comprised of silicon oxide, and a second etching stopper 44 comprised of silicon nitride are formed.

The third insulating film 43 and second etching stopper 44 are formed with interconnect grooves G1 and G2. Further, a contact hole C2 passing through the second insulating film 41 and the first etching stopper 42 to expose the top surface of the first interconnect 50 is formed communicating with the interconnect groove G1.

Inside the communicated contact hole C2 and interconnect groove G1 and inside the interconnect groove G2, the wall surfaces are covered by a barrier metal layer 51a comprised of for example CoWP (cobalt-tungsten alloy containing phosphorus). The insides of these are buried with a conductive layer 52a comprised of for example copper, whereby a contact plug P and second interconnect W2 are formed in the contact hole C2 and interconnect groove G1 and whereby a third interconnect W3 is formed inside the interconnect groove G2.

In the above structure, the second interconnect W2 is connected with the first interconnect 50 laid under it through the contact plug P.

The method of forming this conductive film will be explained next with reference to the drawings.

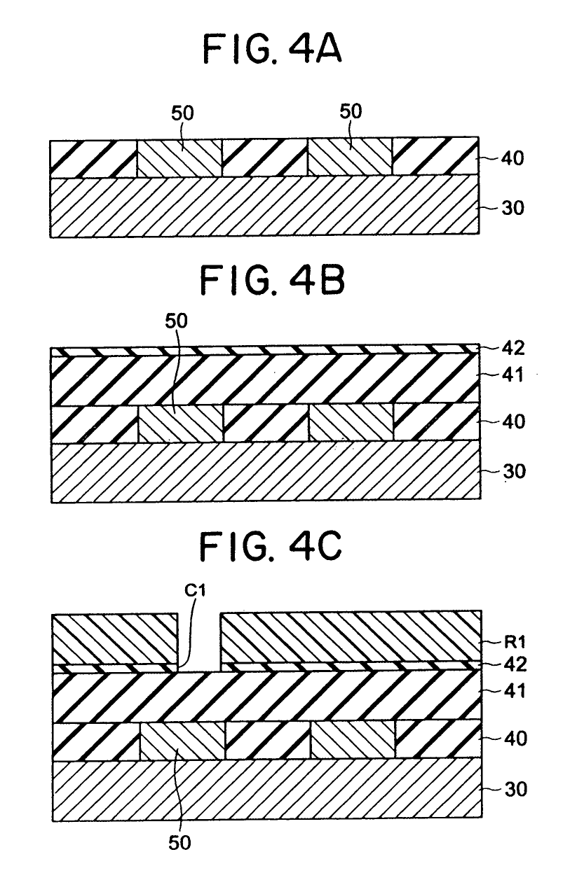

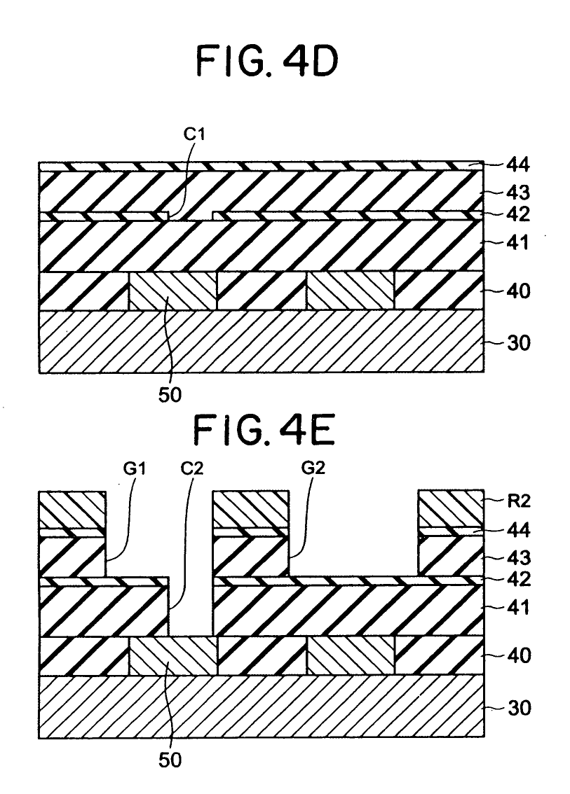

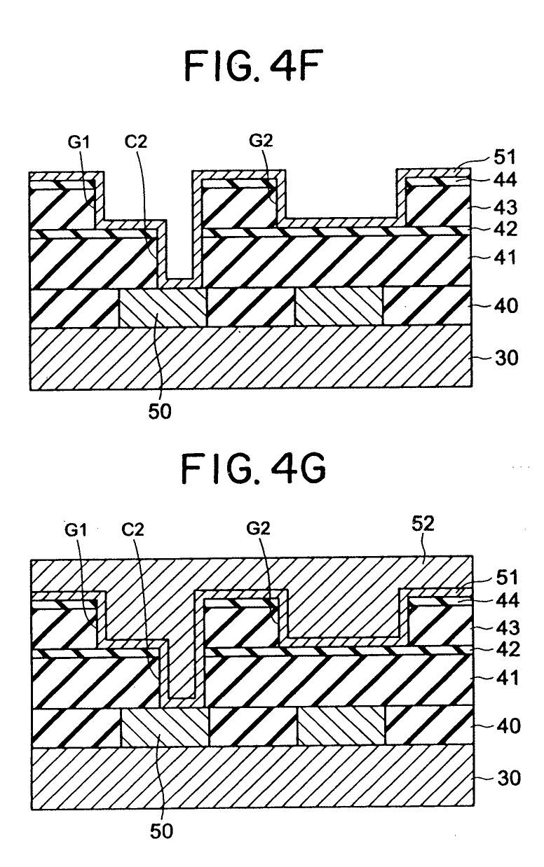

First, as shown in FIG. 4A, a semiconductor substrate 30 formed with a MOS transistor or other semiconductor device (not shown) is covered by silicon oxide deposited on it by for example a CVD (chemical vapor deposition) method etc. to form a first insulating film 40.

Next, the first insulating film 40 is formed with openings reaching the semiconductor substrate 30. These are buried with copper, polycrystalline silicon, tungsten, or another conductive material to form first interconnects 50.

Next, as shown in FIG. 4B, for example a CVD method is used to deposit silicon oxide on the first insulating film 40 and the first interconnects 50 so as to form a second insulating film 41, then for example a CVD method is used to deposit silicon nitride on top of this to form a first etching stopper 42.

Next, as shown in FIG. 4C, a photolithography process is used to form a resist film R1 open to the pattern of a contact hole on the first etching stopper 42, then the resist film R1 is used as a mask for RIE (reactive ion etching) or other etching to form a pattern opening C1 exposing the top surface of the first insulating film 41 through the first etching stopper 42.

Next, as shown in FIG. 4D, for example a CVD method is used to deposit silicon oxide inside the pattern opening C1 and on the first etching stopper 42 to form a third insulating film 3, then for example a CVD method is used to deposit silicon nitride on this to form a second etching stopper 44.

Next, as shown in FIG. 4E, for example a photolithography process is used to form a resist film R2 open to the patterns of interconnect grooves on the second etching stopper 44.

Next, the resist film R2 is used as a mask for RIE or other etching to pattern the second etching stopper 44 and further for RIE or other etching under conditions enabling selective etching of the second insulating film 43 with respect to the first etching stopper 42 so as to form interconnect grooves G1 and G2 in the third insulating film 43 and second etching stopper 44. At this time, by arranging the pattern opening C1 formed in the first etching stopper 42 inside the regions for forming the interconnect grooves G1 and G2, the first insulating film 41 of the pattern opening Cl region is etched away using the first etching stopper 42 as a mask and a contact hole C2 for exposing the top surface of the first interconnect 50 is formed passing through the interconnect groove G1.

Next, as shown in FIG. 4F, a barrier metal layer 51 comprised of for example CoWP (cobalt-tungsten alloy containing phosphorus) is formed as a conductive layer over the entire surface covering the inside wall surfaces of the contact hole C2 and the interconnect grooves G1 and G2 by the electroless plating according to the present invention.

Here, in forming the above barrier metal layer 51, as pre-treatment for electroless plating, it is necessary to activate (catalyze) the target surface (silicon oxide or other insulating film surface and copper, polycrystalline silicon, tungsten, or other conductive film surface) using palladium or another high catalyzing metal. For example, it is possible to activate (catalyze) it by the steps shown below:

Step 1: Pure Water Washing (Pure Water Rinsing)

First, the above wafer W is placed on the spin table 11 shown in FIG. 1, then pure water is fed from the pipe 15 to the surface of the wafer W to wash it by the pure water. After washing, the wafer is spin dried. Note that the pure water may be heated warm water as well. Washing with pure water with ultrasonic waves is also possible.

Step 2: Pre-treatment

Next, the following pre-treatment is performed on the spin table 11 shown in FIG. 1. Note that this step includes spin coating for freely feeding the reagent to the surface of the wafer W on the spin table 11 while spinning the spin table 11, puddling for stopping the spin table to build up the reagent when the reagent covers the wafer, or treatment by the electroless plating apparatus shown in FIG. 2. The method is not particularly limited.

(1) Hydrophilization

First, the reagent is fed to the target surface (silicon oxide, silicon nitride, and first interconnect exposed surfaces) to oxidize it and introduce hydroxy groups (—OH groups) to the surface to hydrophilize the target surface. The reagent may be ozone water, a sulfuric acid or hydrogen peroxide solution, hypochloric acid, an ammonia and hydrogen peroxide solution, ammonium permanganate, or other reagent enabling hydrophilization.

(2) Pure Water Rinsing

Next, treatment the same as step 1 is performed to wash the wafer surface.

(3) Silane (Titanium) Coupling

Next, a silane coupling agent or titanium coupling agent or other coupling agent is fed to the target surface to covalently bond the hydroxy groups and coupling agent.

Due to this, the catalyst palladium colloid of the next step can be coordinately bonded with the coupling agent to improve the bonding strength between the target surface and catalyst palladium colloid.

(4) Pure Water Rinsing

Next, treatment the same as step 1 is performed to wash the wafer surface.

(5) Catalyzation

Next, a reagent including palladium colloid or other catalyst metal protected by stannous chloride is fed to the target surface to bond the coupling agent to the tin atoms of the stannous chloride and bond the catalyst metal to the target surface. As the above reagent, for example, Catalyst 9F of Shipley Co., Enplate Activator 444 of Enthone-OMI, etc. may be used.

(6) Pure Water Rinsing

Next, treatment the same as step 1 is performed to wash the wafer surface.

(7) Activation

Next, for example Accelerator 19, Accelerator 240, etc. of Shipley Co. is fed to the target surface to peel off the stannous chloride from the palladium colloid protected by the stannous chloride and expose the palladium (catalyst metal) and thereby activate it. Reduced copper precipitates on this exposed palladium.

(8) Pure Water Rinsing

Next, treatment the same as step 1 is performed to wash the wafer surface.

(9) Spin Drying

Next, the spin table 11 is spun to spin off the reagent on the wafer by centrifugal force (spin drying).

Note that it is not necessarily required to perform all of the above steps. The (1) hydrophilization, (2) pure water rinsing, (4) pure water rinsing, etc. may be omitted depending on the case.

Step 3: Barrier Metal Electroless Plating

After activating the target surface in the above way, the electroless plating apparatus shown in FIG. 2 is used to feed the electroless plating solution shown below to the wafer W surface and form a barrier metal layer 51 of a uniform thickness on the entire surface of the target surface.

For example, the plating solution in the case of forming the barrier metal by CoP (cobalt containing phosphorus), NiP (nickel containing phosphorus), CoWP (cobalt-tungsten alloy containing phosphorus), NiWP (nickel-tungsten alloy containing phosphorus), CoMoP (cobalt-molybdenum alloy containing phosphorus), and NiMoP (nickel-molybdenum alloy containing phosphorus) will be explained.

The above electroless plating solution contains for example at least a first metal material for supplying the main ingredient of the conductive film for forming the barrier metal layer, a second metal material for supplying an ingredient for enhancing the barrier metal property in the conductive film (not necessary when forming the barrier metal by CoP and NiP), a first complexing agent of an amphoteric ion type (first chelating agent), a second complexing agent for accelerating the plating reaction (second chelating agent), a reducing agent, and a pH adjuster.

The ingredients of the above electroless plating solution will be explained next.

As the first metal material, it is possible to use for example cobalt chloride or nickel chloride or another compound containing cobalt or nickel in a concentration of for example 10 to 100 g/liter.

As the second metal material added according to need, it is possible to use for example an ammonium salt of tungstic acid or molybdic acid or other compound containing tungsten or molybdenum in a concentration of for example 3 to 30 g/liter. Note that when forming a barrier metal of CoP or NiP, the second metal material is not included in the plating solution.

As the first complexing agent of the amphoteric ion type (first chelating agent), for example, it is possible to use glycine, alanine, valine, leucine, isoleucine, methionine, phenylalanine, proline, tryptophan, serine, threonine, tyrosine, asparagine, glutamine, cystine, glutamic acid, aspartic acid, lysine, histidine, arginine, or another amino acid in a concentration of for example 2 to 50 g/liter. The first complexing agent is for producing a stable chelate.

As the second complexing agent for accelerating the plating reaction (second chelating agent), for example, it is possible to use ammonium succinate, ammonium maleate, ammonium citrate, ammonium malonate, ammonium formate, or another organic acid compound (ammonium salt) in a concentration of for example 2 to 50 g/liter. The second complexing agent enables the chelate to be easily reduced and has the effect of accelerating the plating.

As the reducing agent, it is possible to use for example ammonium hypophosphite, formalin, glyoxylic acid, hydrazine, ammonium borate hydroxide, etc. in a concentration of for example 2 to 200 g/liter.

As the pH adjuster, it is possible to use ammonium hydroxide, TMAH (tetramethyl ammonium hydroxide), ammonia water, etc. The amount added is suitably adjusted so that the plating solution becomes for example a range of neutral to alkaline (pH of 7 to 12 or, in the case of the second metal material being included in the plating solution, a pH of 8 to 12).

Here, the ingredients of the above electroless plating solution are held separately in two or three tanks and separately fed from a plurality of not shown pipes to merge at an electroless plating solution feed pipe 26 before the plating cup 21 and be fed to the plating cup 21.

For example, the following ingredients are separately held in tanks and merged at the electroless plating solution feed pipe 26 to be fed to the plating cup 21.

CoP and NiP Barrier Metal

[1] First metal material solution (comprised of first metal material, first chelating agent, second chelating agent, pH adjuster, etc.)

[2] Reducing agent (comprised of reducing agent, pH adjuster, etc.)

The above reagents are adjusted to a pH of 7 to 12 by the pH adjuster and fed to the plating cup 21.

COWP and NiWP (CoMoP and NiMoP) Barrier Metal (1)

[1] First metal material solution (comprised of first metal material, first chelating agent, second chelating agent, pH adjuster, etc.)

[2] Second metal material solution (comprised of second metal material, pH adjuster, etc.) [3] Reducing agent (comprised of reducing agent, pH adjuster, etc.)

The above reagents are adjusted to a pH of 8 to 12 by the pH adjuster and fed to the plating cup 21.

CoWP and NiWP (CoMoP and NiMoP) Barrier Metal (2)

[1] First metal material solution (comprised of first metal material, first chelating agent, second chelating agent, pH adjuster, etc.)

[2] Second metal material solution and reducing agent (comprised of second metal material, reducing agent, pH adjuster, etc.)

The above reagents are adjusted to a pH of 8 to 12 by the pH adjuster and fed to the plating cup 21.

The reagents are held in separate tanks and mixed in front of the plating cup 21 in the above way because for example cobalt easily precipitates as hydroxides in an alkaline solution, so the first chelating agent is charged, but if a reducing agent is mixed in advance with a chelating solution of cobalt, a reduction reaction will proceed due to the reducing agent, the life of the plating solution will become shorter, and a change will arise in the film-forming rate along with time between the start and end of the life of the plating solution. In addition, by addition of the second metal material, it was confirmed that the chelating state becomes unstable and the life of the plating solution becomes shorter.

Therefore, for example, the cobalt chelating solution is held separately from the reducing agent and the second metal material and mixed in front of the plating cup 21.

Note that for the above reasons, several combinations of feed of the plating solution may be considered. Therefore, the invention is not limited to the above combination.

Further, in particular, as the electroless plating solution for forming COWP, it is necessary to make the pH of the plating solution after mixing at least 8. Therefore, it is preferable to adjust the pH of the different systems of reagents before mixing at least 8. This is because to maintain the ammonium tungstate of the second metal material in the solution state, it is necessary to include at least 2 moles of ammonium with respect to 1 mole of tungstic acid. If the ammonium evaporates and the pH falls below 8, the tungstic acid will end up crystallizing. The same applies in the case of ammonium molybdate.

Further, nickel and cobalt easily precipitate in an alkaline solution and precipitate more easily the higher the pH, but by including the second metal material, the cobalt and nickel will become more difficult to precipitate. Therefore, depending on whether or not the second metal material is included, the setting of the pH will differ somewhat.

In the above electroless plating, if the molar ratio of the metal salt, chelating agent (total when using two or more types), and reducing agent is not suitable, the CoP film, CoWP film, etc. will not be formed or even if being formed will end up becoming non-glossy films.

In the above electroless plating solution M, for example by making the percent composition one including at least 3 moles of complexing agent and at least 3 moles of reducing agent with respect to 1 mole of the first metal material, stable formation of a uniform film by electroless plating becomes possible. By adjusting the pH of the electroless plating solution to at least 9 by the pH adjuster, it is possible to obtain a dense, high quality plating film where the surface of the barrier metal layer formed imparts gloss.

In the present embodiment, nitrogen gas, inert gas, or ammonia gas is filled in the plating cup 21 shown in FIG. 2, so it is possible to prevent oxidation of the plating solution by oxygen, a drop in pH due to evaporation of the ammonia from the pH adjuster etc., and precipitation of cobalt hydroxide.

Note that to maintain the plating temperature, the temperature of the nitrogen gas or ammonia gas fed is preferably made the same as the temperature of the plating solution.

When plating in the plating cup 21 as in the present embodiment, the amount of the plating solution used need only be about 100 ml or the same amount as the plating solution used in puddling with for example an 8-inch wafer. By plating for 30 to 120 seconds, it is possible to form a barrier metal film.

When using about 100 mol of the plating solution, about 3 mm of solution is believed to build up on the wafer W in the plating cup 21.

Note that in the case of puddling, when coating the plating solution, about 50 ml is necessary to build up the solution over the entire surface of the wafer W including the amount discarded due to spinning of the spin table 11. If repeating this two times to obtain uniform plating, about 100 ml is believed to be necessary.

The electroless plating solution is preferably adjusted to a temperature to 20 to 95° C. if using a compound containing nickel as the first metal material. When using a compound containing cobalt, a range of 50 to 95° C. is particularly preferable. This is because when using a compound containing nickel or cobalt, if the temperature of the plating solution is less than 20° C. or 50° C., the reaction speed of the plating reaction will be slow and therefore impractical. Further, if over 95° C., the effects of evaporation of the ammonia or boiling of the reagent appear, so the stability of the reagent falls—making this unpreferable.

Further, in the plating cup 21, it is preferable that the temperature of the electroless plating solution become uniform.

To make the temperature of the electroless plating solution M uniform, heaters 111 and 211 are built into the spin table 11 and plating cup 21.

However, the heat of the electroless plating solution easily escapes to the side walls of the plating cup 21 or the spin table 11. Therefore, for example, the center of the spin table 11 ends up becoming higher in temperature than near the side walls. By agitating by the agitator 22 at the time of plating, in addition to the effect of the heaters, it is possible to hold the temperature of the electroless plating solution in the plating cup 21 more uniform.

Further, agitation during the above electroless plating has the following merits in addition to making the temperature uniform.

For example, when using ammonium hypophosphite or another hypophospite as the reducing agent to cause precipitation of cobalt, a cobalt precipitation reaction (1) and hydrogen gas generation reaction (2) occur in general as shown in the following chemical reaction formulas:

Co²⁺+H₂PO₂⁻+H₂O→Co+HPO₃²⁻+2H⁺ (1)

H₂PO₂⁻+H₂LO→HPO₃²⁻+H₂ (2)

Therefore, since hydrogen gas is produced along with precipitation of cobalt, agitation by the agitator 22 can effectively remove the hydrogen gas generated along with the electroless plating reaction from the electroless plating solution, prevent the formation of pinholes in the barrier film after formation, and give a more uniform thickness.

Here, the timing of agitation by the agitator 22 will be explained.

FIG. 5 shows the results of measurement of the thickness of a conductive film formed along with the reaction time of electroless plating.

The electroless plating reaction, as shown in FIG. 5, does not start immediately after the wafer is dipped in the electroless plating solution.

If ending up agitating and moving the electroless plating solution by the agitator 22 at the initial stage A of the start of the electroless plating reaction, the initial reaction ends up being inhibited and conversely the film formation rate becomes slower or film partially cannot be formed.

Therefore, while the time of the initial stage differs depending on the differences in the pre-treatment step for catalyzation using palladium (Pd) or the type, temperature, pH, or other conditions of the electroless plating solution, the agitation is for example preferably started after the elapse of 10 seconds after the electroless plating.

By performing electroless plating in this way, a metal film supplied from the first metal material contained in the electroless plating solution is formed as a conductive film serving as a barrier metal layer. When including a second metal material for enhancing the barrier metal property of the conductive film, an alloy of metals supplied from the first metal material and second metal material is formed.

For example, when using a compound containing cobalt or nickel as the first metal material, it is possible to form a Co (cobalt) film or Ni (nickel) film. When using ammonium hypophosphite as the reducing agent in the electroless plating solution, phosphorus is taken into the metal, so a CoP (cobalt containing phosphorus) film or NiP (nickel containing phosphorus) film is formed.

Further, when using a compound containing cobalt or nickel as the first metal material and using a compound containing tungsten or molybdenum as the second metal material, it is possible to form CoW (cobalt-tungsten alloy), NiW (nickel-tungsten alloy), CoMo (cobalt-molybdenum alloy), or NiMo (nickel-molybdenum alloy).

In this case as well, when using ammonium hypophosphite as the reducing agent in the electroless plating solution, in the same way as above, phosphorus is taken into the alloy, so a CoWP (cobalt-tungsten alloy containing phosphorus) film, NiWP (nickel-tungsten alloy containing phosphorus) film, CoMoP (cobalt-molybdenum alloy containing phosphorus) film, or NiMoP (nickel-molybdenum alloy containing phosphorus) film is formed.

Step 4: Pure Water Washing

After the end of the above electroless plating, the spin table 11 and the plating cup 21 are separated and the electroless plating solution is drained to the outside tank 12.

Next, pure water is filled into the plating cup 21 from the electroless plating apparatus shown in FIG. 2 again and the agitator 22 is operated to wash the wafer W while also washing the plating cup 21.

Next, the pure water is drained by separation of the spin table 11 and the plating cup 21, then pure water is fed to the wafer W surface on the spin table 11 once again to wash it with the pure water and then the wafer is spin dried.

Step 5: Interconnect Electroless Plating

After forming the barrier metal layer 51 on the target surface of the wafer W in this way, using the electroless plating apparatus shown in FIG. 2 once again, as shown in FIG. 4G, electroless plating is performed using for example a cobalt-tungsten alloy film or other barrier metal layer 51 as the catalyst layer (coated layer of target surface in the case of electroless plating) so as to deposit for example copper over the barrier metal layer 51 to bury the insides of the contact hole C2 and the interconnect grooves G1 and G2 and form the conductive layer 52.

Cobalt has a higher catalyst activity than copper, so there is no need to pre-treat the target surface. It is possible to directly deposit copper by electroless plating.

An example of the composition of the plating solution and the plating conditions in electroless plating for depositing copper is shown below:

Electroless Copper Plating Solution Composition and Plating Conditions

| | |
|---|---|
| Copper salt (copper chloride, | 5 to 50 g/liter |
| copper sulfate, copper nitrate, | |
| copper sulfamate, etc.): | |
| Chelating agent (ethylene- | 20 to 40 g/liter |
| diamine, EDTA (ethylene- | |
| diamine tetraacetate), etc.): | |
| Reducing agent (cobalt | 25 to 250 g/liter |
| sulfate etc.): | |
| Temperature: | 20 to 50° C. |
| pH: | 7 to 12 |
| Time: | 1 to 10 min |

When performing the electroless plating under the above conditions by the electroless plating apparatus shown in FIG. 2, the solution containing the copper salt and chelating agent and the solution containing the reducing agent are held in and fed separately from tanks.

Here, the solutions are adjusted to pH=s of 7 to 12 by the above pH adjuster.

The above copper plating does not particularly require pre-treatment of the surface of the barrier metal layer 51, so the copper and barrier metal layer can be formed consecutively. Due to this, the copper and barrier metal layer are metal bonded and a strong bondability can be obtained.

The above copper plating is not limited to the above composition. Any composition can be used so long as copper is precipitated.

Further, it is also possible to form a seed layer of copper by electroless plating, then deposit for example copper by electroplating burying the insides of the contact hole C2 and the interconnect grooves G1 and G2 and thereby form the conductive layer 52.

Note that the electroless plating of copper may also be by plating by puddling by the spin table 11 since the plating temperature is not as high as in the electroless plating of the above-mentioned barrier metal and the pH does not fluctuate much either.

Step 6: Pure Water Washing

Next, after the above electroless plating ends, the spin table 11 is spun to drain the electroless plating solution to the outer tank 12, pure water is fed to the wafer W surface on the spin table 11 to wash it by pure water, then the wafer is spin dried.

For example copper is deposited over the barrier metal layer 51 burying the insides of the contact hole C2 and the interconnect grooves G1 and G2 as explained above to form the conductive layer 52, then the conductive layer 52 and barrier metal layer 51 deposited on the outsides of the contact hole C2 and interconnect grooves G1 and G2 are removed by polishing by a CMP (chemical mechanical polishing) method or etching back by RIE etc.

Due to the above steps, it is possible to form a semiconductor chip shown in FIG. 3.

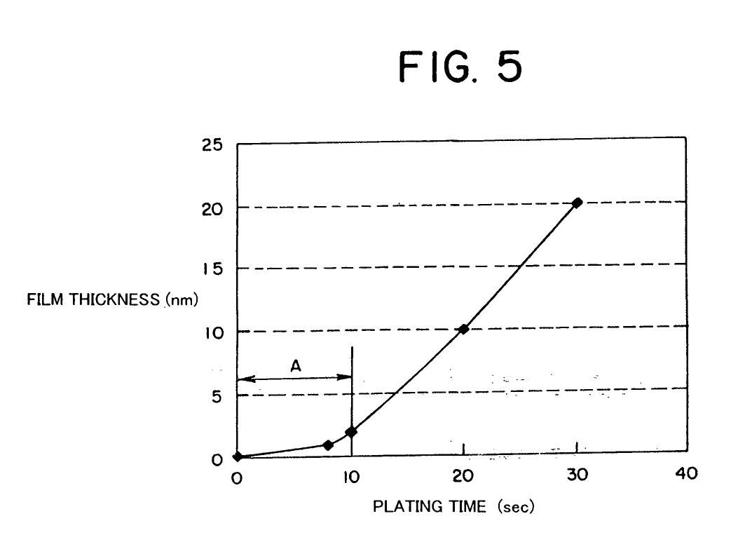

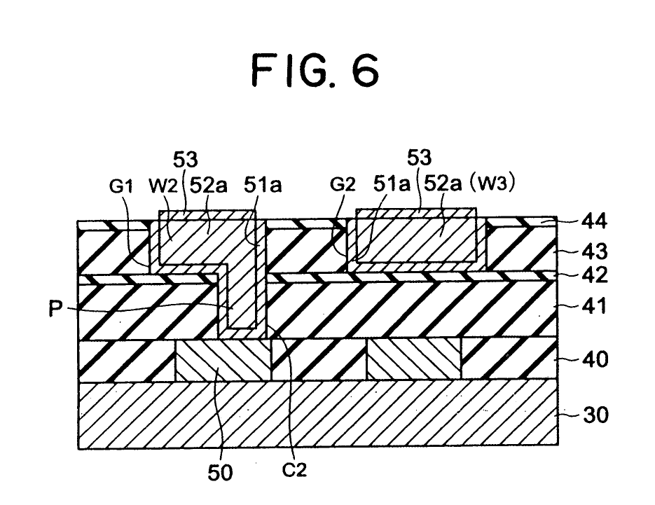

Note that as a step after the formation of the semiconductor chip shown in FIG. 3, as shown in FIG. 6, sometimes barrier metal is selectively formed on only the conductor layer 52 comprised of copper etc. of the semiconductor chip shown in FIG. 3.

This is because if directly forming an interlayer insulating film on a copper film when forming multilayer interconnects of a semiconductor chip, the copper would end up diffusing to the interlayer insulating film. To prevent this, it is necessary to form a barrier metal at the surface of the copper film.

The method of selectively forming a barrier metal film only on the conductive layer 52 (copper interconnects) shown in FIG. 6 will be explained next.

Step 1: Pure Water Washing

First, a wafer W formed with copper interconnects is placed on the spin table 11 shown in FIG. 1. Pure water is fed to the surface of the wafer W from a not shown tank through a pipe 15 to wash the wafer by the pure water. Note that the pure water may be heated warm water and washing by pure water with ultrasonic waves may also be performed. After washing, the wafer is spin dried.

Step 2: Pre-treatment 1

Next, an alkali degreasing agent is fed to the wafer on the spin table 11 shown in FIG. 1 to wash the surface of the copper film and improve the wettability of the surface.

Next, a 2 to 3% hydrochloric acid solution is fed on the wafer W to neutralize and wash the surface.

The above step may be performed by spin coating or by puddling. Note that this pretreatment may be omitted in some cases.

Step 3: Pre-treatment 2

Next, in the state with the target surface of the wafer W shown in FIG. 2 isolated from the outside atmosphere, a hydrochloric solution of palladium chloride (PdCl₂) is fed into the plating cup 21 to replace the copper film surface of the wafer W with palladium and form a catalyst activation layer.

This is for plating by chemical substitution among metals and uses the ionization tendencies of the different metals. Copper is a metal inferior electrochemically compared with palladium, so the electrons discharged along with the dissolution of the copper in the solution migrate to the ions of the precious metal palladium in the solution, whereby palladium is formed on the surface of the inferior metal copper.

For example, as the conditions of the palladium substitution plating, the plating is performed by a hydrochloric acid solution of palladium chloride of a temperature of 30 to 50° C. and a pH of 1 to 2.

Note that the above hydrochloric acid solution of palladium chloride can be used repeatedly if the pH and Pd content are managed. Therefore, it is preferable to circulate and treat it between the not shown tank and plating cup 21.

Step 4: Pure Water Washing

After the hydrochloric acid solution of palladium chloride is recovered in a not shown tank, pure water is fed into the plating cup 21 of FIG. 2 to wash the wafer by pure water. Specifically, pure water is accumulated in the plating cup 21, then the agitator 22 is made to turn to wash the wafer W while washing the plating cup 21 as well.

Next, the spin table 11 and the plating cup 21 are separated to drain the pure water to the outer tank 12. Pure water is again fed to the surface of the wafer W on the spin table 11 from a not shown tank through the pipe 15 to wash it, then the wafer is spin dried.

Step 5: Barrier Metal Selective Electroless Plating

Next, in the plating cup 21 shown in FIG. 2, for example, a film of Co, CoWP, CoMoP, or another barrier metal is selectively formed by electroless plating on the target surface (surface of copper film) catalyzed and activated by the above steps.

This step is similar to that of the above electroless plating, so an explanation will be omitted.

Step 6: Pure Water Washing

After the electroless plating solution is drained to the outer tank 12 or recovered in a not shown tank, the same procedure is followed as in step 4 to wash the wafer W with pure water.

Due to the above step, it is possible to form a semiconductor chip selectively formed with a barrier metal film only on the conductive layer 52 comprised of copper etc. shown in FIG. 6.

According to the method of formation of the conductive film using the electroless plating apparatus according to the present embodiment, by filling heated nitrogen gas into the plating cup 21, it is possible to prevent deterioration due to oxidation of the reagent in an oxygen.atmosphere or precipitation etc. Further, it is, possible to prevent a drop in pH due to evaporation of the ammonia gas in the plating solution, possible to prevent precipitation of hydroxides of cobalt ions when the plating solution contains for example cobalt, possible to prevent fluctuations in the plating rate due to changes in the plating solution along with time, and possible to plate uniformly.

Further, since the plating solution is fed on to the wafer W after making the plating solution strike the top surface of the agitator 22 once, it is possible to prevent collision of the electroless plating solution on the palladium (Pd) catalyst layer on the wafer W surface.

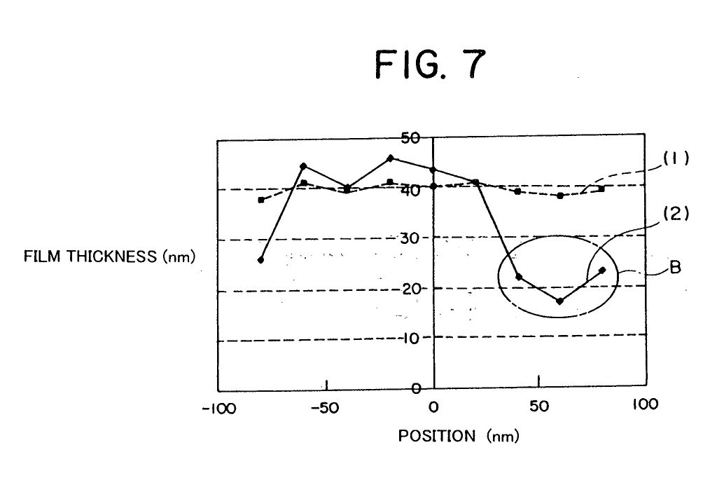

FIG. 7 shows the results of measurement of the uniformity of thickness of the conductive film in the wafer W plane in the case (1) of making the plating solution strike the top surface of the agitator once, then feeding the plating solution to the wafer W surface for electroless plating and the case (2) of feeding electroless plating solution from the ceiling of the plating cup 21 to the wafer W for electroless plating.

As shown in FIG. 7, it is learned that in the case (1) of making the plating solution strike the top surface of the agitator once, then feeding the plating solution to the wafer W surface for the electroless plating, a conductive film with an extremely good uniformity of thickness is formed in the wafer W plane.

On the other hand, it is learned that in the case (2) of feeding electroless plating solution from the ceiling of the plating cup 21 to the wafer W for electroless plating, the Pd catalyst layer is damaged by the collision of the electroless plating solution fed at the position of the part B of the wafer W, the rate of growth of the conductive film is affected, and the thickness of the conductive film after formation becomes smaller.

As explained above, when feeding the electroless plating solution on to the wafer W, it is possible to ease the impact on the Pd catalyst layer formed on the wafer W and possible to form a conductive film having a uniform thickness.

Further, by agitating the electroless plating solution by the agitator 22 at the time of electroless plating, in addition to the effects of the heaters 111 and 211 provided at the spin table 11 and the plating cup 21, it is possible to improve the uniformity of the temperature of the electroless plating solution. Further, it is possible to prevent the formation of pinholes in the film after formation by removal of the hydrogen gas produced along with the electroless plating reaction due to the agitation. Therefore, it is possible to form a conductive film with a more uniform thickness.

Note that by agitating the solution except at the initial stage of the electroless plating reaction, the initial reaction of the electroless plating reaction will not be obstructed as explained above.

### Second Embodiment

FIG. 8 is a schematic view of the configuration of an electroless plating apparatus according to the present embodiment.

The electroless plating apparatus according to the present embodiment differs from the first embodiment in the structure of the spin table.

In the electroless plating apparatus according to the first embodiment, as shown in FIG. 2, the area of the wafer W was greater than even the area of the spin table 11 and the plating cup 21 was placed on the edges of the wafer W through the seal member 23 for the electroless plating.

However, as shown in FIG. 2, if the area of the spin table 11 is smaller than the area of the wafer W, since the bottom of the wafer W at the part where the plating cup 21 is placed is held by the spin table 11, when the plating cup 21 and the spin table 11 are mated, the wafer W is liable to end up being broken by the pressure, so in the present embodiment, the area of the spin table and the area of the wafer W are made equal sizes.

As shown in FIG. 8, in the electroless plating apparatus according to the present embodiment, the spin table 11b is provided with a large number of clamping holes 112 for suction clamping of the wafer W on its holding surface. It holds a wafer W by a not shown suction pump. At the same time, a gas blowing groove 113 is provided around the outer periphery of the holding surface holding the wafer by suction clamping.

The gas blowing groove 113 has a step difference in the height direction between the inner periphery and the outer periphery to enable the inert gas or nitrogen gas blown out to escape to the sides of the spin table 11b.

The gas blowing groove 113 is provided at its bottom surface with gas blowing holes 114 for blowing out inert gas or nitrogen gas and is designed to blow out inert gas or nitrogen gas from the gas blowing holes 114 from a not shown gas feed tank.

According to the above electroless plating apparatus according to the present embodiment, in addition to effects similar to those of the first embodiment, since the area of the spin table 11b is made a size equal to the area of the wafer W, when placing the plating cup 21 at the edges of the wafer 2 via the seal member 23, it is possible to prevent the wafer W from being broken due to the pressure at that time.

Further, at the time of electroless plating, since the wafer W is held by suction by the clamping holes 112 formed in the holding surface and simultaneously inert gas or nitrogen gas is blown out from the gas blowing groove 113 formed at the outer periphery, it is possible to prevent the plating solution or other reagent from traveling along the outer periphery of the wafer W and being sucked into the clamping holes 112 when separating the plating cup 21 from it.

Further, the reagent no longer travels along the outer periphery of the wafer W and deposits at the back surface and edges of the wafer and contamination of the back surface of the wafer can be prevented.

### Third Embodiment

The electroless plating apparatus according to the present embodiment differs from the first and second embodiments in the structure of the spin table.

In the electroless plating apparatuses according to the first and second embodiments, the area of the spin table had an area equal to or less than the area of the wafer W. The plating cup 21 was placed at the edges of the wafer W through a seal member 23 for electroless plating.

In the present embodiment, the area of the spin table is made an area larger than the area of the wafer W.

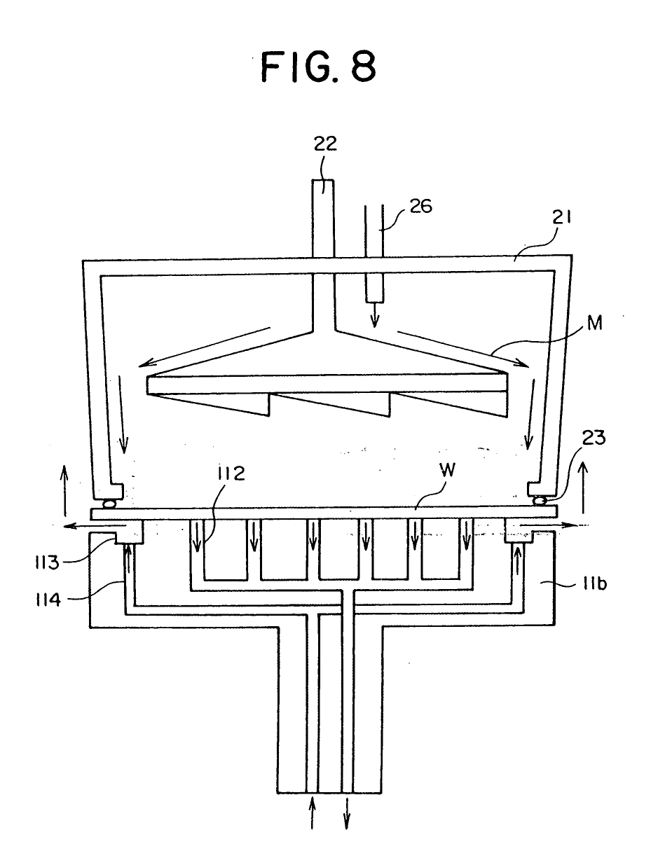

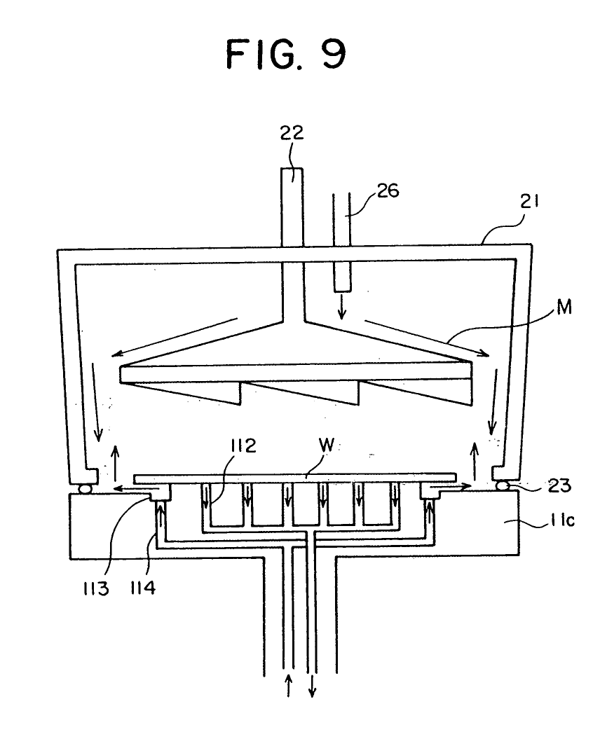

FIG. 9 is a schematic view of the configuration of an electroless plating apparatus according to the present embodiment.

As shown in FIG. 9, in the electroless plating apparatus according to the present embodiment, the area of the spin table 11c is greater than even the area of the wafer W, the holding surface is provided with a large number of clamping holes 112 for suction clamping the wafer W in the same way as in the second embodiment, the outer periphery of the holding surface for holding the wafer is provided with a gas blowing groove 113, and the gas blowing groove 113 is provided with gas blowing holes 114 for blowing out inert gas or nitrogen gas.

The gas blowing groove 113 has a step difference in the height direction between the inner periphery and the outer periphery to enable the inert gas or nitrogen gas blown out to escape to the sides of the spin table 11c.

In the electroless plating apparatus of the above configuration, the area of the spin table 11 is larger than the area of the wafer W, and the plating cup 21 is placed on the edges of the spin table 11c through the seal member 23 at the time of electroless plating.

In the middle of the electroless plating after mating of the plating cup 21 and the spin table 11c, as shown in FIG. 9, the electroless plating solution is fed from the electroless plating solution feed pipe 26 while inert gas or nitrogen gas is blown out from below the outer periphery of the wafer W, so the electroless plating is performed while preventing the plating solution from penetrating to the clamping holes 112 or the back surface of the wafer.

According to the electroless plating apparatus according to the present embodiment, in addition to effects similar to those of the first embodiment, since the plating cup 21 is placed on the spin table 11c at the time of the electroless plating, the entire surface of the wafer can be effectively plated and the wafer will not end up being broken by the pressure at that time.

Further, it is possible to prevent the plating solution from being sucked into the clamping holes 112 and possible to prevent the back surface of the wafer from being contaminated by deposition of the plating solution on the back surface of the wafer.

Note that the inert gas or nitrogen gas blown out from the gas blowing groove 113 rises in the plating solution to emerge from the plating solution while preventing the plating solution from penetrating to the back surface of the wafer, but the inert gas or nitrogen gas is free from the problems of reaction with the plating solution etc.

When using nitrogen gas as the gas blown out from the gas blowing groove 113, it is possible to prevent the Co ingredient of the plating solution from precipitating as hydroxides in an oxygen atmosphere.

Further, the gas blown out from the gas blowing groove 113 will not affect the target surface since it rises up in the plating solution.

### Fourth Embodiment

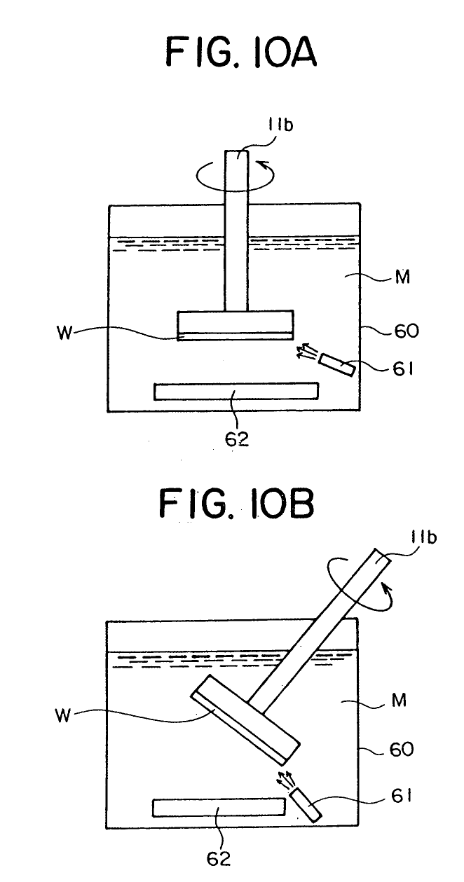

FIG. 10A and FIG. 10B are views of the configuration of an electroless plating apparatus according to the present embodiment.

In the electroless plating apparatus according to the present embodiment, a spin table 11b having the structure explained in the second embodiment is used to dip a wafer W face down in a plating tank 60 holding the electroless plating solution M for electroless plating.

The plating tank 60 has built into it a not shown heater for uniformly heating the electroless plating solution held in the plating tank 60.

At the bottom of the plating tank 60, a discharging means 61 for discharging an inert gas, nitrogen gas, or electroless plating solution M toward the target surface of the wafer W dipped face down is provided. Further, an ultrasonic wave generator 62 for generating ultrasonic waves in a pulse manner is arranged facing the target surface of the wafer W.

Further, the plating tank is sealed air-tight by a not shown lid. An inert gas, nitrogen gas, or ammonia gas is fed from a not shown gas feeding means and the electroless plating solution M is kept from exposure to an oxygen atmosphere in this configuration.

The electroless plating by the electroless plating apparatus of the above configuration will be explained next.

First, before dipping the wafer W in the plating tank 60, as explained in the second embodiment, the wafer W is held by suction by the clamping holes formed in the holding surface and, at the same time, an inert gas or nitrogen gas is blown out from the gas blowing groove formed in the outer periphery.

In this state, the wafer W is dipped face down in the plating tank 60 holding the electroless plating solution M by the spin table 11b.

At this time, it is possible to dip the wafer W parallel with respect to the surface of the electroless plating solution M as shown in FIG. 10A or to dip it providing a predetermined angle so as to enable the escape of hydrogen gas produced when forming a conductive film containing cobalt on the target surface as shown in FIG. 10B.

At the time of dipping of the wafer W, gas is blown out from the outer periphery of the spin table, so the electroless plating solution M is not sucked into the clamping holes and it is possible to prevent the plating solution from penetrating to the back surface of the wafer and wet only the target surface with the plating solution.

In the middle of the above electroless plating, as explained in the first embodiment, by operating the spin table 11b for the time except the initial stage of the electroless plating reaction, it is possible to prevent accumulation of the electroless plating solution M at the target surface due to the agitation action and to remove the hydrogen gas produced at the time of the electroless plating from the target surface.

As shown in FIG. 10B, even at an angle enabling the gas produced to easily escape, if the surface tension of the electroless plating solution is too great, the gas will sometimes accumulate at the target surface and not be fully exhausted.

Therefore, in accordance with need, accumulation of hydrogen gas at the target surface is prevented by discharging inert gas, nitrogen gas, or electroless plating solution M from the discharging means 61 toward the target surface of the wafer W for the time except for the initial stage of the electroless plating reaction.

Alternatively, by applying ultrasonic waves in a pulse manner to the target surface of the wafer W from the ultrasonic wave generator 62, accumulation of hydrogen gas at the target surface is similarly prevented. Here, applying ultrasonic waves continuously could make the thickness of the electroless plating uneven, so for example it is preferable to apply ultrasonic waves periodically setting predetermined time intervals between them.

In FIG. 10A and FIG. 10B, the discharging means 61 and ultrasonic wave generator 62 are provided, but it is also possible to provided just one of the above or to use both.

According to the electroless plating apparatus according to the present embodiment, by using the spin table 11b having a gas blowing groove at its outer periphery to dip the wafer W in the plating tank 60 face down, it is possible to dip the wafer W in the plating solution while preventing contamination of its back surface. Further, since there is an agitation effect and a hydrogen gas removing effect due to spinning of the spin table 11, it is possible to form a conductive film uniformly.

Further, by providing the discharging means 61 for discharging inert gas, nitrogen gas, or plating solution in the plating tank 60 or the ultrasonic wave generator 62, it becomes possible to remove the hydrogen gas produced along with the electroless reaction at the target surface.

### Fifth Embodiment

FIG. 11 is a schematic view of the configuration of an electroless plating apparatus according to the present embodiment.

In the present embodiment, to prevent the cobalt ions in the electroless plating solution from precipitating as hydroxides in an alkaline aqueous solution and to prevent a drop in pH of the electroless plating solution, as shown in FIG. 11, the plating cup 21 and spin table 11 and other devices in the first to third embodiments and an electroless plating solution tank etc. are placed inside an air-tightly sealed plating chamber 2.

The plating chamber 2 has connected to it a gas feed pipe 2a for feeding an inert gas, nitrogen gas, or ammonia gas and a gas exhaust pipe 2b for exhausting the gas in the plating chamber 2.

The plating chamber 2 further has a standby chamber 3 for loading and unloading wafers W connected to it through a movable shutter 4.

The standby chamber 3, in the same way as the plating chamber 2, has a gas feed pipe 3a for feeding an inert gas, nitrogen gas, or ammonia gas and a gas exhaust pipe 3b for exhausting gas in the standby chamber 3 connected to it.

The plating solution tank 71 is connected to the plating tank 70 and is designed to feed and recover electroless plating solution M through the pipes 26 and 72 in the plating cup 21 by a not shown pump etc.

The plating solution tank 71 holds an electroless plating solution M having the ingredients explained in the first embodiment, the plating solution tank 71 is provided with a not shown heater, and the electroless plating solution M is held at a predetermined temperature.

For example, the plating solution tank 71 holds about 1 liter of the electroless plating solution M. A plating solution tank 71 is provided inside the plating chamber 2 under an inert gas, nitrogen gas, or ammonia gas, so the plating solution can be maintained without deterioration for at least 5 hours and plating of at least 10 wafers W becomes possible.

Further, the plating solution tank 71 is provided with a pH adjusting means.

That is, the plating solution tank 71 has connected to it a pH adjuster tank 74 holding a pH adjuster 73 through a pipe 74a having a valve 74b.

Further, the plating solution tank 71 is provided with a pH meter 76 having a pH detector 75 dipped in the electroless plating solution M and is provided with a pH controller 77 connected to the pH meter 76 and valve 74b.

At the pH adjusting means of the above configuration, a pH detection signal of the plating solution tank 71 by the pH detector 75 is output from the pH meter 76 to the pH controller 77. When the pH detected is less than 9, the pH controller 77 operates the valve 74b so as to add a commensurate amount of pH adjuster 73 to the plating solution tank 71 to control the pH of the electroless plating solution M in the plating solution tank 71 to maintain it at least at 9.

The electroless plating by the above electroless plating apparatus will be explained next.

First, a wafer W to be treated is placed inside the standby chamber 3 filled with an inert gas, nitrogen gas, or ammonia gas from the gas feed pipe 3a.

Further, the shutter 4 is opened and a not shown loading robot is used to place the wafer W on the spin table 11. At that time, the plating chamber 2 is similarly filled with an inert gas, nitrogen gas, or ammonia from the gas feed pipe 2a.

When the plating chamber 2 is filled with nitrogen gas or an inert gas, it is necessary to make the inside of the plating chamber 2 a positive pressure, while when filling the inside of the plating chamber 2 with ammonia gas, it is necessary to maintain the pressure at not more than the vapor pressure due to the ammonia ingredient in the electroless plating solution M.

Further, in the plating chamber 2 filled with nitrogen gas, an inert gas, ammonia gas, or other gas, electroless plating is performed by the plating cup 21 and the spin table 1 as explained in the first embodiment.

After the end of the electroless plating in the plating chamber 2, the shutter 4 is opened and the wafer W is unloaded using a not shown loading robot into the standby chamber 3 filled with an inert gas, nitrogen gas, or ammonia gas from the gas feed pipe 3a.

According to the electroless plating apparatus of the above configuration, by holding the plating cup 21, spin table 11, and other devices in the plating chamber 2 kept in an atmosphere of nitrogen gas, an inert gas, or ammonia gas and loading and unloading the wafer W to be loaded and unloaded into and from the plating chamber 2 into and from the standby chamber 3 kept in an atmosphere similar to the plating chamber 2, the electroless plating solution is kept from being exposed to an air atmosphere and it is possible to prevent the production of hydroxides of cobalt ions in the electroless plating solution and a drop in the pH.

Further, since the pH of the electroless plating solution M is kept at least at 9 in this configuration, fluctuation of the composition of the electroless plating solution M due to precipitation etc. can be prevented, the life of the electroless plating solution M can be prolonged, the amount of the electroless plating solution M which ends up being wasted can be reduced, and the amount of the electroless plating solution M used can be reduced.

Here, production of cobalt hydroxide can be prevented by eliminating the oxygen atmosphere. Therefore, all of nitrogen gas, inert gas, and ammonia gas are effective.

Further, to prevent a drop in pH, when using ammonia water for adjustment of the pH, ammonia gas is particularly effective. For example, when using TMAH (tetramethyl ammonium hydroxide) for adjustment of the pH, since carbon dioxide gas in the air is taken in and the pH of the electroless plating solution easily falls, nitrogen, an inert gas, and ammonia gas shutting out the air are effective.

Further, by holding the ingredients to be contained in the electroless plating solution M at a predetermined temperature in the tank 71, feeding them from a pipe 26 to the inside of the plating cup 21, and simultaneously recovering the plating solution in the plating cup 21 from the pipe 72 and returning it to the plating solution tank 71 again, it is possible to recirculate the plating solution in the plating cup 21 and keep the composition of the plating solution uniform at all times.

### Sixth Embodiment

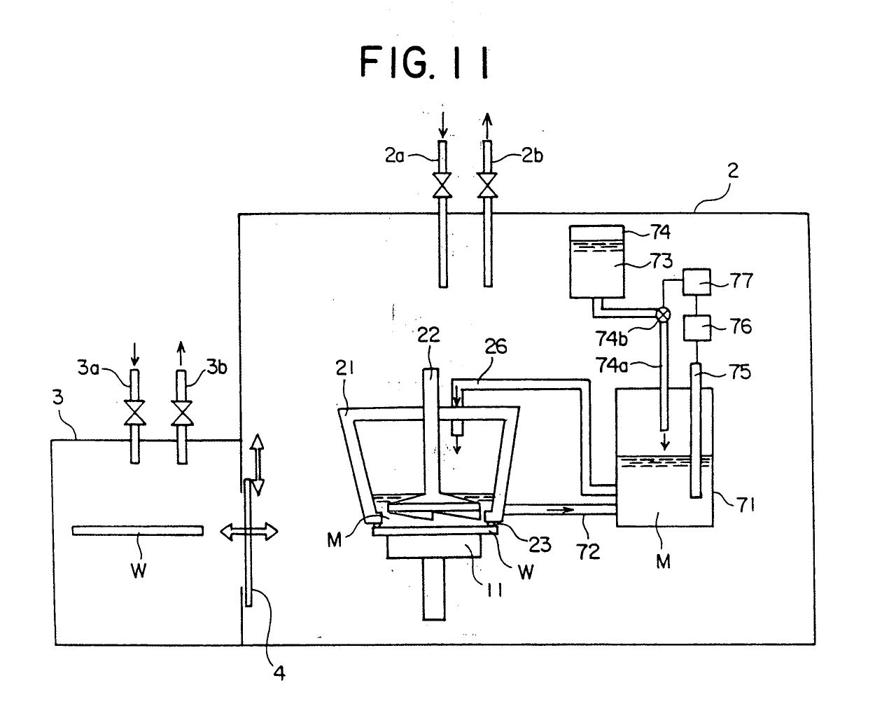

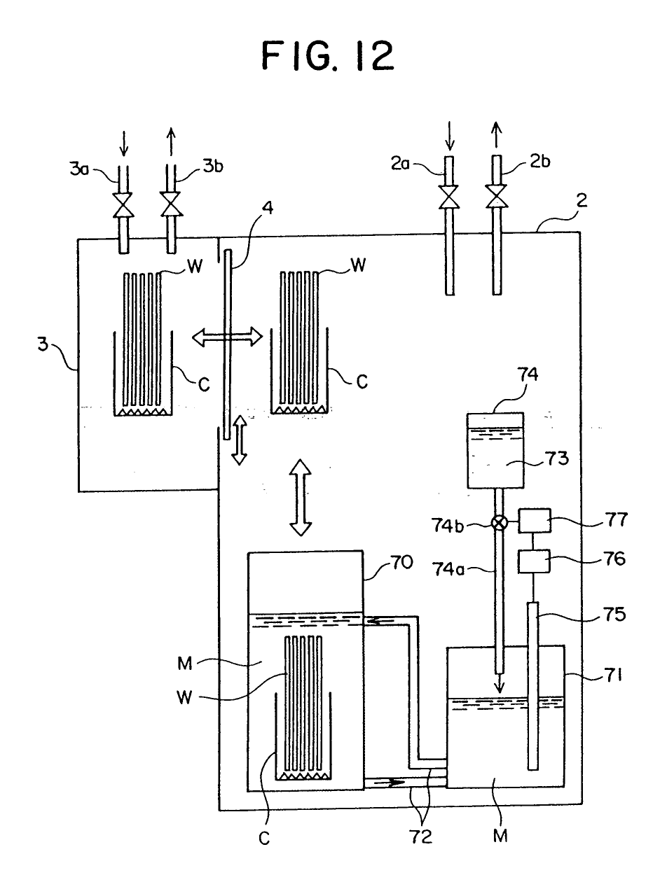

FIG. 12 is a schematic view of the configuration of an electroless plating apparatus according to the present embodiment.

In the present embodiment, to prevent the cobalt ions in the electroless plating solution from precipitating as hydroxides in an alkali aqueous solution and to prevent a drop in pH of the electroless plating solution, as shown in FIG. 12, the plating tank 70 and the electroless plating solution tank 71 etc. are placed inside an air-tightly sealed plating chamber 2.

The plating chamber 2 has connected to it a gas feed pipe 2 a for feeding an inert gas, nitrogen gas, or ammonia gas and a gas exhaust pipe 2b for exhausting the gas in the plating chamber 2.

The plating chamber 2 further has a standby chamber 3 for loading and unloading wafers W connected to it through a movable shutter 4.

The standby chamber 3, in the same way as the plating chamber 2, has a gas feed pipe 3a for feeding an inert gas, nitrogen gas, or ammonia gas and a gas exhaust pipe 3b for exhausting gas in the standby chamber 3 connected to it.

The plating tank 70 holds an electroless plating solution M similar to that of the first embodiment, the plating tank 70 is provided with a not shown heater, and the electroless plating solution is held at a predetermined temperature.

The plating solution tank 71 is connected to the plating tank 70 and is designed to feed and recover the electroless plating solution M through the pipe 72 in the plating tank 70 by a not shown pump etc.

The plating solution tank 71 holds an electroless plating solution M having the ingredients explained in the first embodiment, the plating solution tank 71 is provided with a not shown heater, and the electroless plating solution M is held at a predetermined temperature.

For example, the plating solution tank 71 holds about 1 liter of the electroless plating solution M. A plating solution tank 71 is provided inside the plating chamber 2 under an inert gas, nitrogen gas, or ammonia gas, so the plating solution can be maintained without deterioration for at least 5 hours and plating of at least 10 wafers W becomes possible.

Further, the plating solution tank 71 is provided with a pH adjusting means.

That is, the plating solution tank 71 has connected to it a pH adjuster tank 74 holding a pH adjuster 73 through a pipe 74a having a valve 74b.

Further, the plating solution tank 71 is provided with a pH meter 76 having a pH detector 75 dipped in the electroless plating solution M and is provided with a pH controller 77 connected to the pH meter 76 and valve 74b.

At the pH adjusting means of the above configuration, a pH detection signal of the plating solution tank 71 by the pH detector 75 is output from the pH meter 76 to the pH controller 77. When the pH detected is less than 9, the pH controller 77 operates the valve 74b so as to add a commensurate amount of pH adjuster 73 to the plating solution tank 71 to control the pH of the electroless plating solution M in the plating solution tank 71 to maintain it at least at 9.

The electroless plating by the above electroless plating apparatus will be explained next.

First, a cassette C holding a plurality of wafers W to be treated is placed inside the standby chamber 3 filled with an inert gas, nitrogen gas, or ammonia gas from the gas feed pipe 3a.

Further, the shutter 4 is opened and a not shown loading robot is used to dip a wafer W in the plating tank 70 holding the electroless plating solution M. At that time, the plating chamber 2 is similarly filled with an inert gas, nitrogen gas, or ammonia from the gas feed pipe 2a.

When the plating chamber 2 is filled with nitrogen gas or an inert gas, it is necessary to make the inside of the plating chamber 2 a positive pressure, while when filling the inside of the plating chamber 2 with ammonia gas, it is necessary to maintain the pressure at not more than the vapor pressure due to the ammonia ingredient in the electroless plating solution M.

Further, in the plating chamber 2 filled with nitrogen gas, an inert gas, ammonia gas, or other gas, electroless plating is performed in the plating tank 70.

After the end of the electroless plating in the plating chamber 2, the shutter 4 is opened and the cassette C holding a plurality of wafers W is unloaded using a not shown loading robot into the standby chamber 3 filled with an inert gas, nitrogen gas, or ammonia gas from the gas feed pipe 3a.

According to the electroless plating apparatus of the above configuration, by holding the plating tank 70, the plating solution tank 71, and other devices in the plating chamber 2 kept in an atmosphere of nitrogen gas, an inert gas, or ammonia gas and loading and unloading the wafer W to be loaded and unloaded into and from the plating chamber 2 into and from the standby chamber 3 kept in an atmosphere similar to the plating chamber 2, the electroless plating solution is kept from being exposed to an air atmosphere and it is possible to prevent the production of hydroxides of cobalt ions in the electroless plating solution and a drop in the pH.

Further, since the pH of the electroless plating solution M is kept at least at 9 in this configuration, fluctuation of the composition of the electroless plating solution M due to precipitation etc. can be prevented, the life of the electroless plating solution M can be prolonged, the amount of the electroless plating solution M which ends up being wasted can be reduced, and the amount of the electroless plating solution M used can be reduced.

Further, by holding the ingredients to be contained in the electroless plating solution M at a predetermined temperature at the plating solution tank 71, feeding them to the plating tank 70 from the pipe 72, and while doing so recovering plating solution in the plating tank 70 from the pipe 72 and returning it again to the plating solution tank 71, it is possible to circulate the plating solution in the plating tank 70 and keep the plating solution uniform in composition at all times.

### Seventh Embodiment

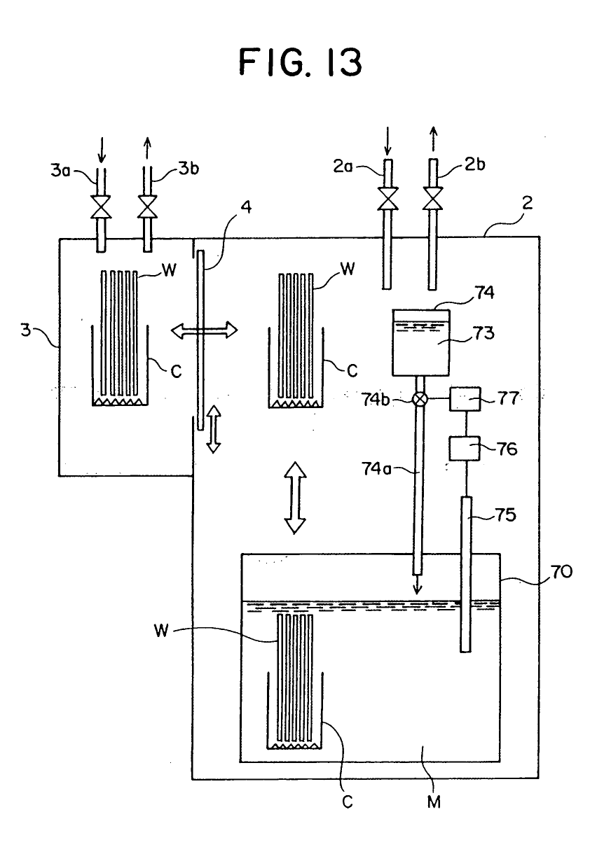

FIG. 13 is a schematic view of the configuration of an electroless plating apparatus according to the present embodiment.

In actuality, the electroless plating apparatus is similar to that of the sixth embodiment. The plating tank 70 and plating solution tank 71 in the sixth embodiment are formed integrally.

The rest of the configuration is similar to that of the sixth embodiment, so the explanation will be omitted.

According to the electroless plating apparatus of the above configuration, by housing the plating tank 70 and other devices in the plating chamber 2 under a nitrogen gas or inert gas or ammonia gas atmosphere and loading and unloading wafers W to be loaded and unloaded into and out from the plating chamber 2 from a standby chamber 3 under an atmosphere similar to the plating chamber 2, the electroless plating solution is free from being exposed to the air atmosphere and production of hydroxides of cobalt ions in the electroless plating solution and a drop in pH can be prevented.

Further, since the pH of the electroless plating solution M is held to at least 9 in this configuration, fluctuation of the composition of the electroless plating solution M due to precipitation etc. can be prevented, the life of the electroless plating solution M can be prolonged, the amount of the electroless plating solution M which ends up being wasted can be reduced, and the amount of the electroless plating solution M used can be reduced.

### Eighth Embodiment

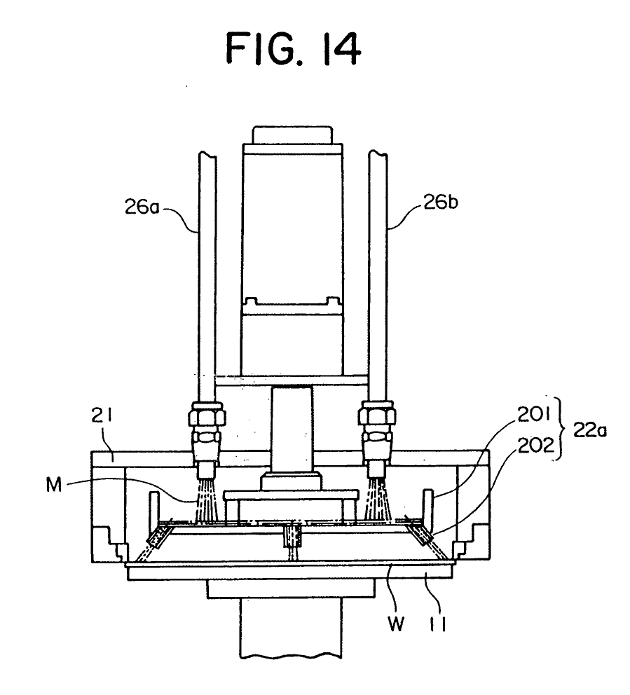

FIG. 14 is a schematic view of the configuration of an electroless plating apparatus according to the present embodiment.

The electroless plating apparatus according to the present embodiment differs from the first embodiment mainly in the configuration of the agitator.

As shown in FIG. 14, in the electroless plating apparatus according to the present embodiment, two electroless plating solution feed pipes 26a and 26b are arranged passing through the top surface of the plating cup 21.

The agitator 22a has a container 201 for receiving electroless plating solution fed from the electroless plating solution feed pipes 26a and 26b and a plurality of small diameter feed pipes 202 of relatively small inside diameters formed in the bottom surface of the outer periphery of the container 201 and feeding the electroless plating solution M accumulated in the container 201 to the wafer W.

The rest of the configuration is similar to that in the first embodiment.

In the electroless plating apparatus of the above configuration, the electroless plating solution M is fed from the electroless plating solution feed pipes 26a and 26b to the inside of the container 201 of the agitator 22a once, then the electroless plating solution is fed from the plurality of small diameter feed pipes 202 formed at the bottom surface of the outer periphery of the container 201 to the wafer W, whereby electroless plating is performed.

According to the present embodiment, by the electroless plating solution M fed from the electroless plating solution feed pipes 26a and 26b striking the container 201 of the agitator 22a once and its impact being eased and then the electroless plating solution M being fed from the small diameter feed pipes 202 of a small distance from the wafer W to the wafer W, it is possible to ease the impact of the electroless plating solution on the wafer W at the time of feeding and possible to form a conductive film having a uniform thickness.

Further, by operating the agitator 22a when feeding the above electroless plating solution M, the electroless plating solution M fed from the small diameter feed pipes 202 formed at the bottom surface of the outer periphery of the container 201 is spun out to the side walls of the plating cup 21 by the centrifugal force of the spinning and the electroless plating solution M is fed to the wafer W along the side walls of the plating cup 21, whereby the impact of the electroless plating solution on the wafer W at the time of feeding can be eased.

### Ninth Embodiment

FIG. 15A is a view of the configuration of an electroless plating apparatus according to the present embodiment.

Further, FIG. 15B is a perspective view of the agitator, while FIG. 15C is a sectional view of the agitator.

The electroless plating apparatus according to the present embodiment differs from the first embodiment in the configuration of the agitator and the electroless plating solution feed pipe.

As shown in FIG. 15A to FIG. 15C, in the electroless plating apparatus according to the present embodiment, the electroless plating solution feed pipe 26 is partially joined with the agitator in structure.

That is, the agitator 22b has a through hole 204 connected to the electroless plating solution feed pipe 26 at the center of its shaft 203 and a plating solution holder 205 of a hollow structure connected to an end of the through hole 204.

The plating solution holder 205 has a sectional shape of a downward facing pentagon as shown in FIG. 15C and is formed with a plurality of slits 206 at its front end.

The rest of the configuration is similar to that in the first embodiment.

In the electroless plating apparatus of the above configuration, the electroless plating solution M fed from the electroless plating solution feed pipe 26 is held in the plating solution holder 205 through the through hole 204 formed in the shaft 203 of the agitator. The electroless plating solution is fed from the plurality of slits 206 formed at the bottom surface of the plating solution holder 205 to the wafer W, whereby electroless plating is performed.

According to the present embodiment, by the electroless plating solution M fed from the electroless plating solution feed pipe 26 striking the plating solution holder 205 of the agitator 22b once and its impact being eased and then the electroless plating solution being fed from the plurality of slits 206 formed in the plating solution holder 205 to the wafer W, it is possible to ease the impact of the electroless plating solution on the wafer W at the time of feeding and possible to form a conductive film having a uniform thickness.

### 10th Embodiment

FIG. 16A is a view of the configuration of an electroless plating apparatus according to the present embodiment, while FIG. 16B is a perspective view of the plating cup.

The electroless plating apparatus according to the present embodiment differs from the first embodiment in the configuration of the plating cup and the electroless plating solution feed pipe.

As shown in FIG. 16A and FIG. 16B, in the electroless plating apparatus according to the present embodiment, a nozzle 260 is formed at an end of the electroless plating solution feed pipe 26 and electroless plating solution M is blown out to the side walls of the plating cup 21 a through the nozzle 260.

The plating cup 21 a is formed with a spiral shaped groove 220 extending from the top to bottom at the side walls.

The rest of the configuration is similar to that in the first embodiment.

In the electroless plating apparatus of the above configuration, the electroless plating solution M is blown out from the nozzle 260 connected to the electroless plating solution feed pipe 26 to the spiral shaped groove 220 formed at the side walls of the plating cup 21. The fed electroless plating solution M descends along the spiral shaped groove 220 to be fed on to the wafer W, whereby electroless plating is performed.

Note that it is necessary to blow out the electroless plating solution M from the nozzle 260 in the direction of formation of the groove 220 by a force required for the electroless plating solution M to descend along the spiral shaped groove 220.

According to the present embodiment, by the electroless plating solution M being fed from the nozzle 260 connected to the electroless plating solution feed pipe 26 to the spiral shaped groove 220 of the plating cup 21a and the electroless plating solution M being fed along the spiral shaped groove 220 to the wafer W, it is possible to ease the impact of the electroless plating solution on the wafer W at the time of feeding and possible to form a conductive film having a uniform thickness.

### 11th Embodiment

FIG. 17A is a view of the configuration of an electroless plating apparatus according to the present embodiment, while FIG. 17B is a perspective view of the plating cup.

The electroless plating apparatus according to the present embodiment differs from the first embodiment in the configuration of the plating cup and the electroless plating solution feed pipe.

As shown in FIG. 17A and FIG. 17B, in the electroless plating apparatus according to the present embodiment, like in the 10th embodiment, a nozzle 260 is formed at an end of the electroless plating solution feed pipe 26 and the electroless plating solution M is blown out to the side walls of the plating cup 21b through the nozzle 260.

The plating cup 21b is formed with a spiral shaped groove 221 extending from the top to bottom at the side walls. The spiral shaped groove 221, unlike in the 10th embodiment, becomes smaller in distance from the center of the plating cup the further to the bottom.

The rest of the configuration is similar to that in the first embodiment.

In the electroless plating apparatus of the above configuration, the electroless plating solution M is blown out from the nozzle 260 connected to the electroless plating solution feed pipe 26 to the spiral shaped groove 221 formed at the side walls of the plating cup 21b. The fed electroless plating solution M descends along the spiral shaped groove 221 to be fed on to the wafer W, whereby electroless plating is performed.

Note that it is necessary to blow out the electroless plating solution M from the nozzle 260 in the direction of formation of the groove 221 by a force required for the electroless plating solution M to descend along the spiral shaped groove 221.

According to the present embodiment, by the electroless plating solution M being fed from the nozzle 260 connected to the electroless plating solution feed pipe 26 to the spiral shaped groove 221 of the plating cup 21b and the electroless plating solution M being fed along the spiral shaped groove 221 to the wafer W, it is possible to ease the impact of the electroless plating solution on the wafer W at the time of feeding and possible to form a conductive film having a uniform thickness.

### 12th Embodiment

FIG. 18A is a view of the configuration of an electroless plating apparatus according to the present embodiment, while FIG. 18B is a perspective view of a plating cup.

The electroless plating apparatus according to the present embodiment differs from the first embodiment in the configuration of the plating cup and electroless plating solution feed pipes.

As shown in FIG. 18A and FIG. 18B, in the electroless plating apparatus according to the present embodiment, like in the 10th and 11th embodiments, a nozzle 260 is formed at an end of the electroless plating solution feed pipe 26. The electroless plating solution M is blown out to the side walls of the plating cup 21c through the nozzle 260.

The plating cup 21c has an inclined surface 222 with a conical side surface. The inclined surface 222 becomes smaller in distance from the center of the plating cup the further from the top to the bottom.

The rest of the configuration is similar to that of the first embodiment.

In the electroless plating apparatus of the above configuration, the electroless plating solution M is blown out to the side walls of the plating cup 21c from the nozzle 260 connected to the electroless plating feed pipe 26. The fed electroless plating solution M, as shown in FIG. 18B, travels downward as if circling the inclined surface 222 of the side walls of the plating cup 21c, whereby the electroless plating solution M is fed on to the wafer W and electroless plating is performed.

Note that the electroless plating solution M is blown out from the nozzle 260 for example in parallel to the wafer W by a force required for the electroless plating solution M to descend so as to circle the inclined surface 222.

According to the present embodiment, the electroless plating solution M is fed to the side walls of the plating cup 21 from the nozzle 260 connected to the electroless plating solution feed pipe 26 and travels so as to circle the inclined surface 222, whereby the electroless plating solution M is fed to the wafer W. Due to this, the impact of the electroless plating solution striking the wafer W when fed can be eased and a conductive film having a uniform thickness can be formed.

### 13th Embodiment

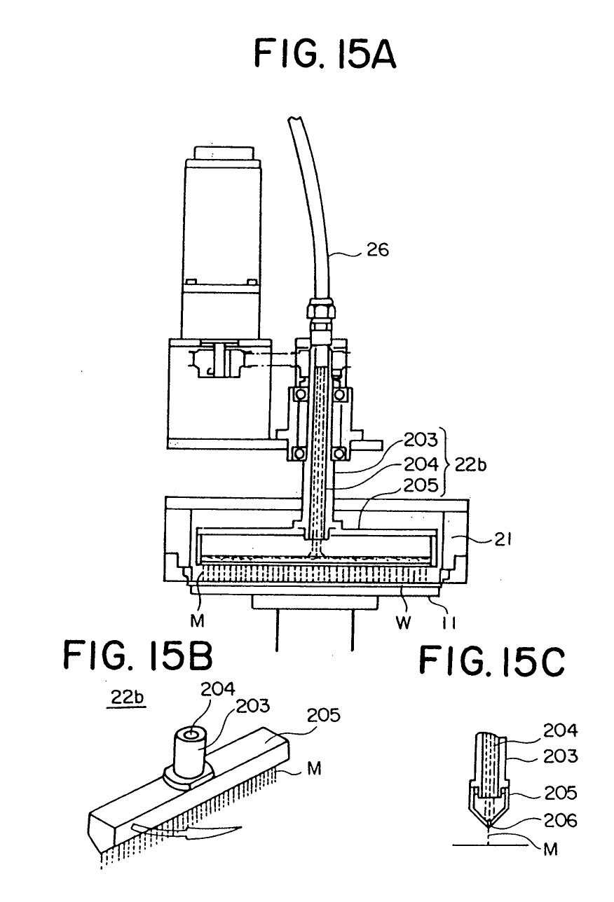

FIG. 19A is a view of the configuration of an electroless plating apparatus according to the present embodiment, while FIG. 19B is an enlarged view of the part D of FIG. 19A.

The electroless plating apparatus according to the present embodiment, like in the third embodiment, has a spin table of an area of a size larger than the area of the wafer W, but has electroless plating solution feed pipes configured differently from the third embodiment.

As shown in FIG. 19A, in the electroless plating apparatus according to the present embodiment, two electroless plating solution feed pipes 26a and 26b are arranged passing through the top surface of edges of the plating cup 21.

The electroless plating solution feed pipes 26a and 26b, unlike the third embodiment, do not feed the electroless plating solution M to the top surface of the agitator 22, but feed the electroless plating solution M to the top of the outer periphery of the spin table 11c not holding the wafer W.

Further, in the electroless plating apparatus according to the present embodiment, like in the third embodiment, the area of the spin table 11c is larger than the area of the wafer W, and the holding surface, like in the third embodiment, is provided with a large number of clamping holes 112 for suction clamping the wafer W. Further, the outer periphery of the holding surface holding the wafer W is provided with a gas blowing groove 113. This gas blowing groove 113 is provided with gas blowing holes 114 for blowing out an inert gas or nitrogen gas.

In the electroless plating apparatus of the above configuration, after the plating cup 21 and the spin table 11c are mated, as shown in FIG. 19A and FIG. 19B, the electroless plating solution M is fed above the outer periphery of the spin table 11c not holding the wafer W from the electroless plating solution feed pipes 26a and 26b, while an inert gas or nitrogen gas is blown out from below the outer periphery of the wafer W, so the plating solution is prevented from building up on the wafer W while the plating solution is prevented from penetrating the clamping holes 114 or to the back surface of the wafer and electroless plating is performed.

According to the electroless plating apparatus according to the present embodiment, it is possible to exhibit effects similar to those of the third embodiment.

Further, by feeding the electroless plating solution M on to the part of the spin table 11c not holding the wafer W, it is possible to avoid the disadvantages due to the plating solution striking the wafer W.

### 14th Embodiment

The present embodiment shows a specific type of spin table 11b used in the second embodiment.

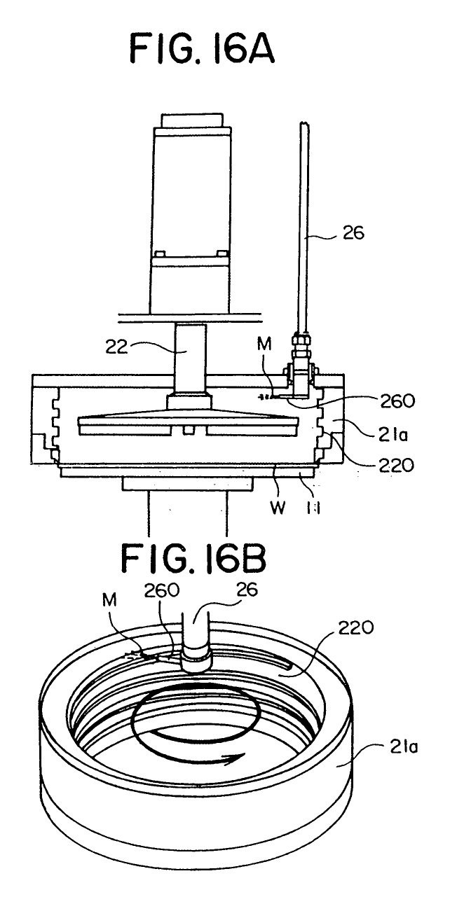

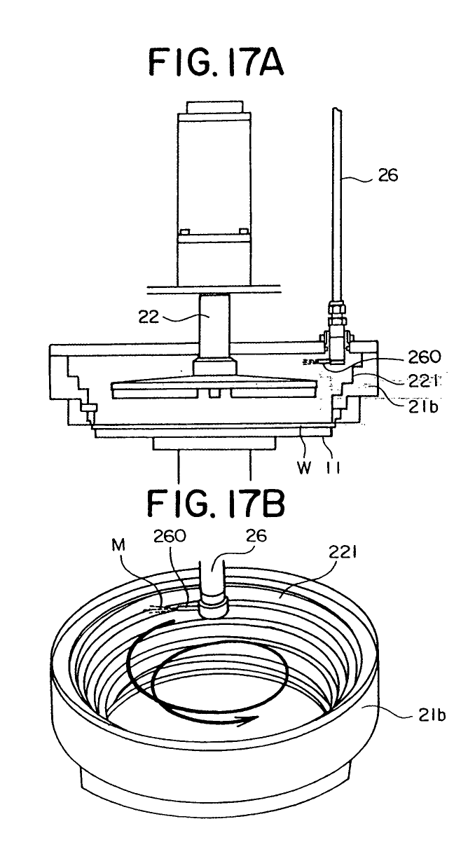

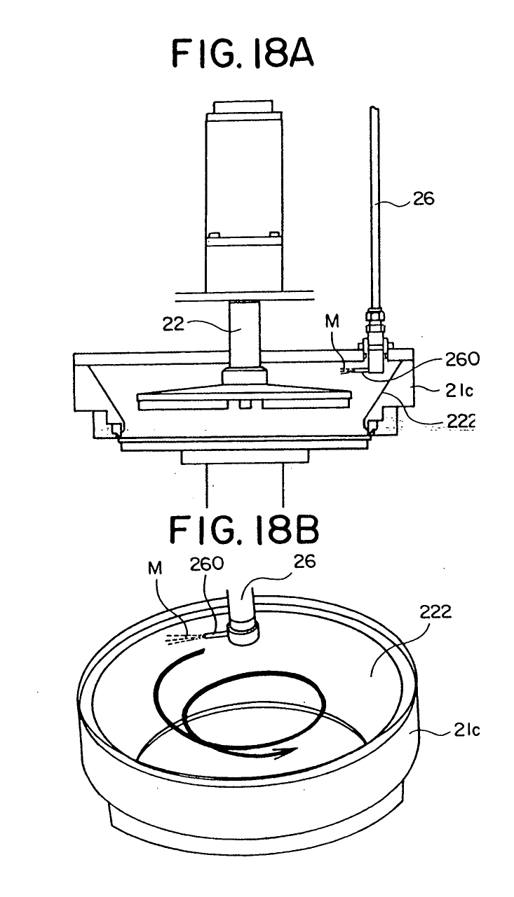

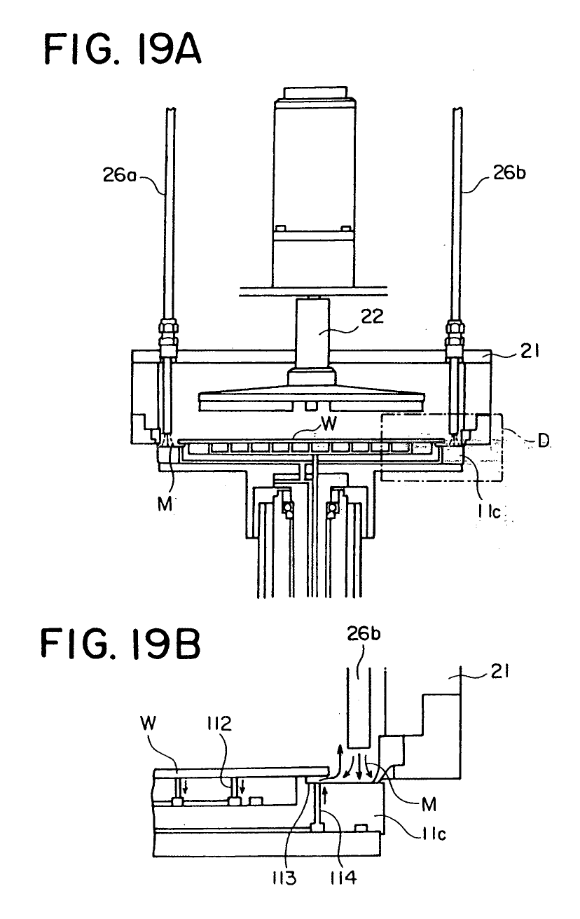

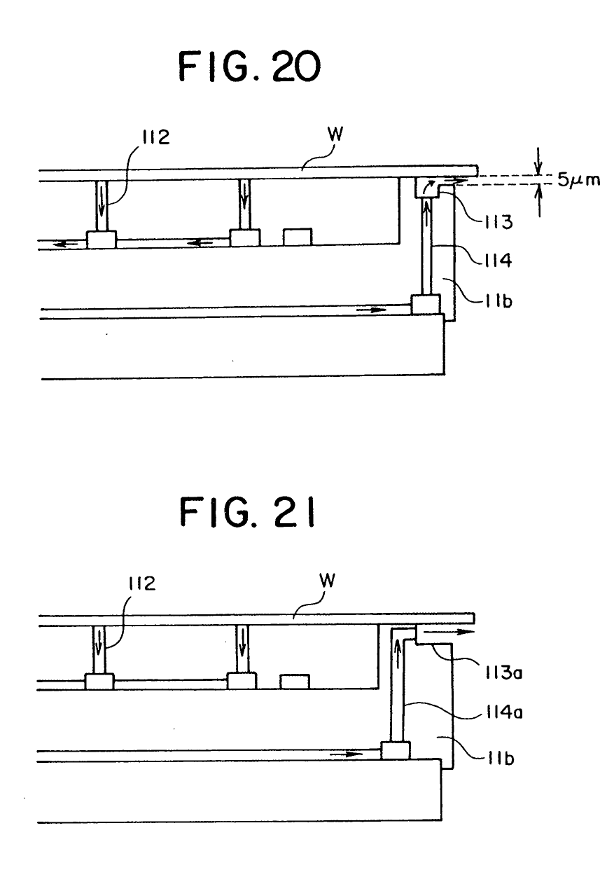

FIG. 20 is a view of the configuration of an edge of a spin table of an electroless plating apparatus according to the present embodiment.

As shown in FIG. 20, the spin table 11b used in the electroless plating apparatus according to the present embodiment is provided with a gas blowing groove 113 around the outer periphery of the holding surface holding the wafer W by suction clamping. The gas blowing groove 113 has a step difference in the height direction between the inner periphery and the outer periphery to enable the inert gas or nitrogen gas blown out to escape to the sides of the spin table 11b and has a clearance with the wafer W at the outer periphery of about 5 μm.

The gas blowing groove 113 is provided at its bottom surface with gas blowing holes 114 for blowing out an inert gas or nitrogen gas and is designed to blow out gas including an inert gas or nitrogen from the gas blowing holes 114 from a not shown gas feed tank.

In the above electroless plating apparatus, the gas blown out from the gas blowing holes 114 formed at the bottom surface at the gas blowing groove 113 strikes the bottom surface of the wafer W and escapes to the sides from the clearance between the outer periphery of the gas blowing groove 113 of the spin table 11b and the wafer W.

According to the electroless plating apparatus according to the present embodiment, at the time of electroless plating, the wafer W is held by suction by the clamping holes 112 formed at the holding surface. Simultaneously, an inert gas or nitrogen gas is blown out sideways from the gas blowing groove 113 formed at the outer periphery. Therefore, it is possible to prevent the plating solution or other reagent from being sucked into the clamping holes 112 along the outer periphery of the wafer W.

Further, the reagent no longer deposits at the back surface and edges of the wafer along the outer periphery of the wafer W and contamination of the back surface of the wafer can be prevented.

### 15th Embodiment

The present embodiment, in the same way as the 14th embodiment, shows a specific type of spin table 11b used in the second embodiment.

FIG. 21 is a view of the configuration of an edge of a spin table of an electroless plating apparatus according to the present embodiment.

In the present embodiment, as shown in FIG. 21, the spin table 11b is provided with a gas blowing groove 113a around the outer periphery of the holding surface holding the wafer W by suction clamping. The gas blowing groove 113a has a venting structure in the outer peripheral direction to enable the inert gas or nitrogen gas blown out to escape to the sides of the spin table 11b.

The gas blowing groove 113a is provided with gas blowing holes 114a for blowing out an inert gas or nitrogen gas at the side surface at the inner periphery side and is designed to blow out inert gas or nitrogen-containing gas from the gas blowing holes 114a from a not shown gas feed tank.

In the above electroless plating apparatus, the gas blown out from the gas blowing holes 114a formed at the side surface at the inner periphery side of the gas blowing groove 113a is blown out to the sides without striking the bottom surface of the wafer W unlike the 14th embodiment.

According to the electroless plating apparatus according to the present embodiment, at the time of electroless plating, the wafer W is held by suction by the clamping holes 112 formed at the holding surface. Simultaneously, an inert gas or nitrogen gas is blown out sideways from the gas blowing groove 113a formed at the outer periphery. Therefore, it is possible to prevent the plating solution or other reagent from being sucked into the clamping holes 112 along the outer periphery of the wafer W.

Further, the reagent no longer deposits at the back surface and edges of the wafer along the outer periphery of the wafer W and contamination of the back surface of the wafer can be prevented.

### 16th Embodiment

The present embodiment, in the same way as the 14th and 15th embodiments, shows a specific type of spin table 11b used in the second embodiment.

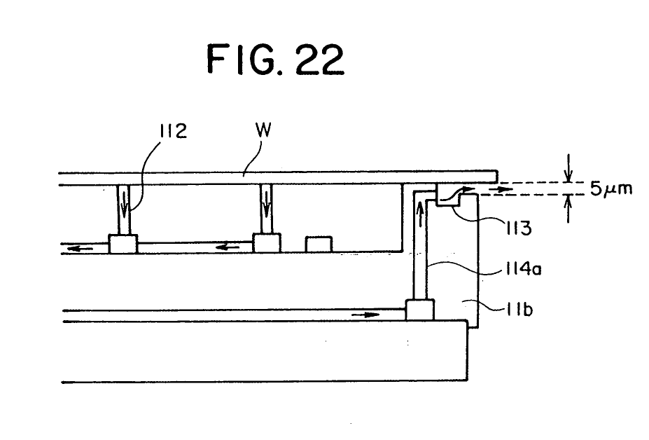

FIG. 22 is a view of the configuration of an edge of a spin table of an electroless plating apparatus according to the present embodiment.

In the present embodiment, as shown in FIG. 22, the spin table 11b is provided with a gas blowing groove 113 around the outer periphery of the holding surface holding the wafer W by suction clamping. The gas blowing groove 113 has a step difference in the height direction between the inner periphery and the outer periphery to enable the inert gas or nitrogen gas blown out to escape to the sides of the spin table 11b and has a clearance with the wafer W at the outer periphery of about 5 μm.

The gas blowing groove 113, as in the 15th embodiment, is provided with gas blowing holes 114a for blowing out an inert gas or nitrogen gas at the side surface at the inner periphery side and is designed to blow out an inert gas or nitrogen-containing gas from the gas blowing holes 114a from a not shown gas feed tank.

In the above electroless plating apparatus, the gas blown out from the gas blowing holes 114a formed at the side surface at the inner periphery side of the gas blowing groove 113 strikes the side surface of the outer periphery side of the gas blowing groove 113 and strikes the bottom surface of the wafer W to thereby escape to the sides from the clearance between the outer periphery of the gas blowing groove 113 of the spin table 11b and the wafer W.

According to the electroless plating apparatus according to the present embodiment, at the time of electroless plating, the wafer W is held by suction by the clamping holes 112 formed at the holding surface. Simultaneously, an inert gas or nitrogen gas is blown out sideways from the gas blowing groove 113 formed at the outer periphery. Therefore, it is possible to prevent the plating solution or other reagent from being sucked into the clamping holes 112 along the outer periphery of the wafer W.

Further, the reagent no longer deposits at the back surface and edges of the wafer along the outer periphery of the wafer W and contamination of the back surface of the wafer can be prevented.

### 17th Embodiment

The present embodiment shows a specific type of spin table used for the embodiments of the present invention.

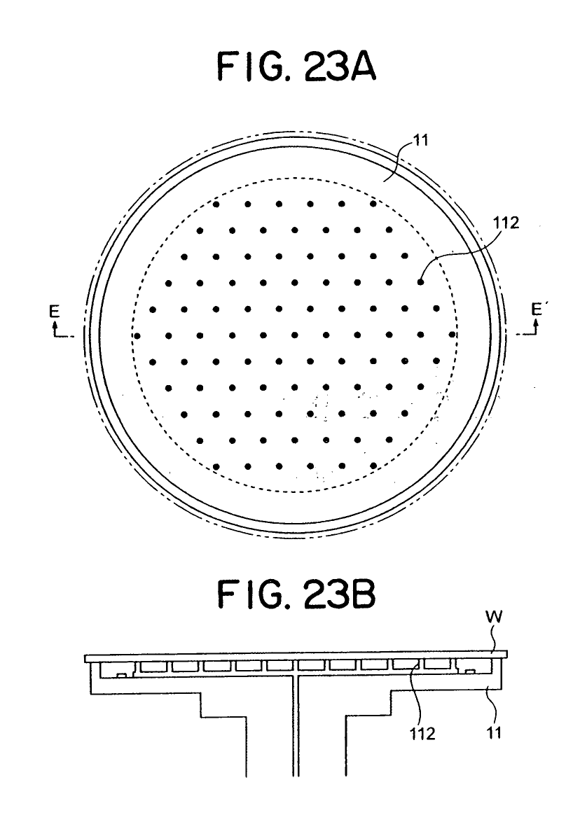

FIG. 23A is a plan view of a spin table used in an electroless plating apparatus according to the present embodiment, while FIG. 23B is a sectional view along the line E-E= of FIG. 23A.

As shown in FIG. 23A, in the spin table 11 used for the electroless plating apparatus according to the present embodiment, clamping grooves 112 are arranged at equal intervals in the horizontal direction in the figure. A plurality of rows of clamping holes 112 arranged in the horizontal direction are formed in the vertical direction shifted by half the intervals of the clamping holes. Note that while not shown, it is also possible to form a gas blowing groove and gas blowing holes at the outer periphery of the spin table 11.

By the spin table 11 of this configuration, as shown in FIG. 23B, the wafer W is held by suction by the clamping grooves 112.

### 18th Embodiment

The present embodiment shows a specific type of spin table used for the embodiments of the present invention.

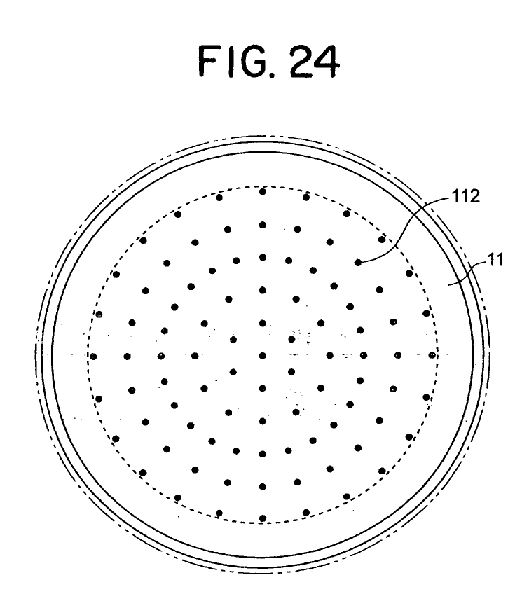

FIG. 24 is a plan view of a spin table used in an electroless plating apparatus according to the present embodiment.

As shown in FIG. 24, in the spin table 11 used for the electroless plating apparatus according to the present embodiment, a plurality of clamping grooves 112 are formed in concentric circles at the holding surface of the spin table 11. Note that the sectional view of the spin table 11 becomes one similar to that of the 17th embodiment. Note that while not shown, it is also possible to form a gas blowing groove and gas blowing holes at the outer periphery of the spin table 11.

By the spin table 11 of this configuration, the wafer W is held by suction by the clamping grooves 112.

### 19th Embodiment

The present embodiment shows a specific type of spin table used for the embodiments of the present invention.

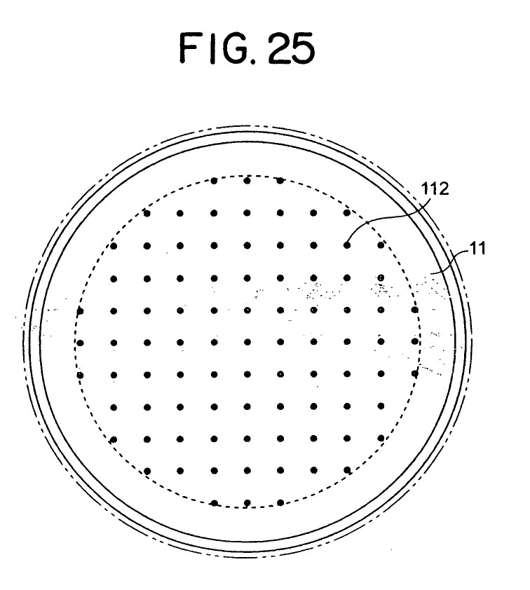

FIG. 25 is a plan view of a spin table used in an electroless plating apparatus according to the present embodiment.

As shown in FIG. 25, in the spin table 11 used for the electroless plating apparatus according to the present embodiment, a plurality of clamping grooves 112 are formed in a lattice at the holding surface of the spin table 11. Note that the sectional view of the spin table 11 becomes one similar to that of the 17th embodiment. Note that while not shown, it is also possible to form a gas blowing groove and gas blowing holes at the outer periphery of the spin table 11.

By the spin table 11 of this configuration, the wafer W is held by suction by the clamping grooves 112.

### 20th Embodiment

The present embodiment shows a specific type of spin table used for the embodiments of the present invention.

FIG. 26A is a plan view of a spin table used in an electroless plating apparatus according to the present embodiment, while FIG. 26B is a sectional view along the line F-F= of FIG. 26A.

As shown in FIG. 26A, in the spin table 11 used for the electroless plating apparatus according to the present embodiment, concentric circular clamping grooves 115 are formed at predetermined intervals. As shown in FIG. 26B, at the bottom surfaces of the clamping grooves 115 are formed a plurality of clamping holes 112. Note that while not shown, it is also possible to form a gas blowing groove and gas blowing holes at the outer periphery of the spin table 11.

By the spin table 11 of this configuration, as shown in FIG. 26B, the wafer W is held by suction by the clamping grooves 115 formed with the plurality of clamping holes 112 overall.

### 21st Embodiment

The present embodiment shows a specific type of spin table used for the embodiments of the present invention.

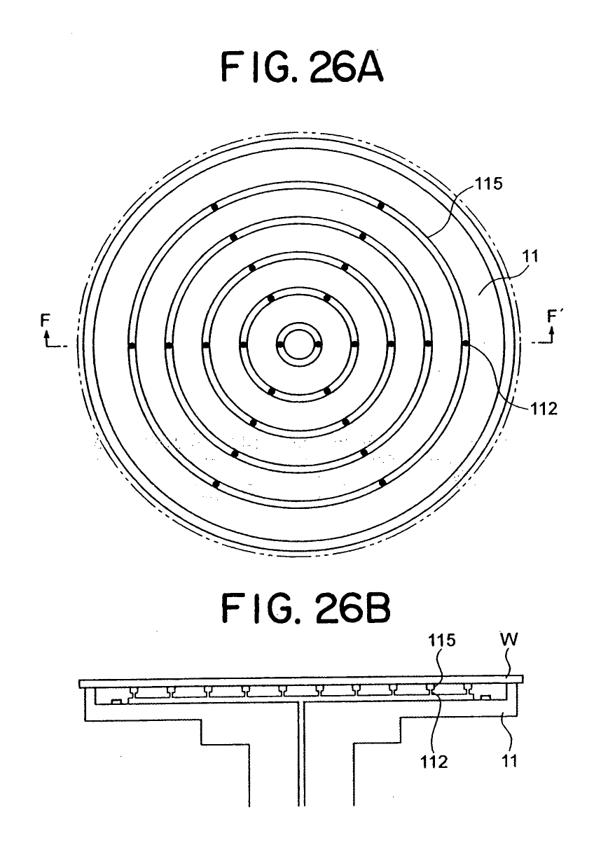

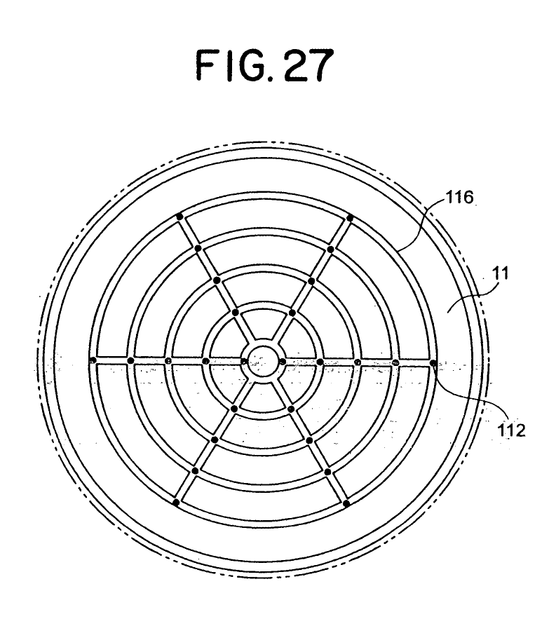

FIG. 27 is a plan view of a spin table used in an electroless plating apparatus according to the present embodiment.

As shown in FIG. 27, in the spin table 11 used for the electroless plating apparatus according to the present embodiment, clamping grooves 116 are formed concentrically circularly and so as to connect the concentric circles. At the bottom surfaces of the clamping grooves 116 are formed a plurality of clamping holes 112. Note that while not shown, it is also possible to form a gas blowing groove and gas blowing holes at the outer periphery of the spin table 11.

By the spin table 11 of this configuration, the wafer W is held by suction by the clamping grooves 116 formed with the plurality of clamping holes 112 overall.

### 22nd Embodiment

The present embodiment shows a specific type of spin table used for the embodiments of the present invention.

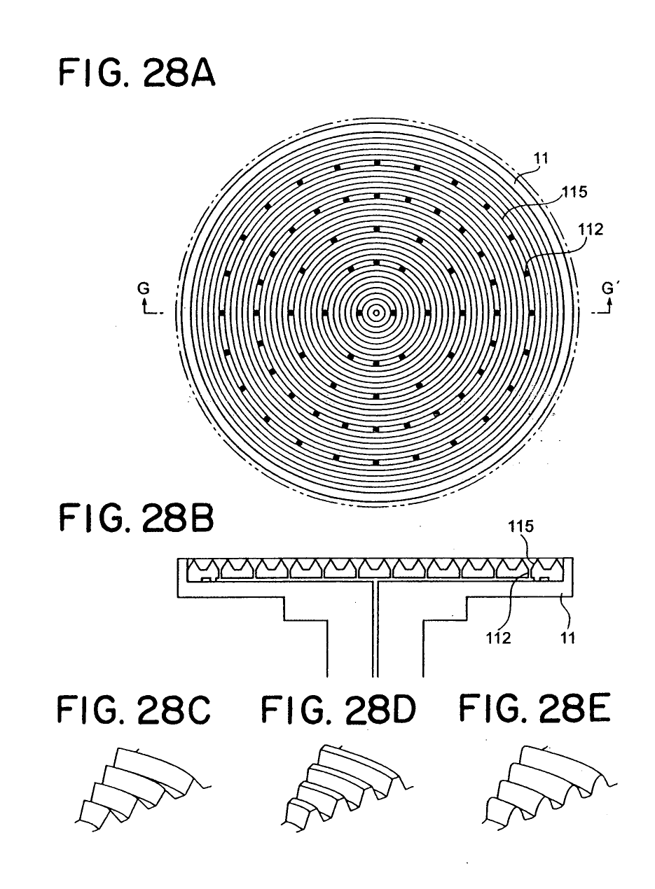

FIG. 28A is a plan view of a spin table used for the electroless plating apparatus according to the present embodiment, while FIG. 28B is a sectional view along the line G-G= of FIG. 28A.

As shown in FIG. 28A and FIG. 28B, in the spin table 11 used for the electroless plating apparatus according to the present embodiment, a large number of concentric circular clamping grooves 115 are formed large in opening area in the wafer direction. At the bottom surfaces of the clamping grooves 115 are formed clamping holes 112 on concentric circles. While not shown, it is also possible to form a gas blowing groove and gas blowing holes at the outer periphery of the spin table 11.

Note that the projections of the clamping grooves 115 by which the wafer W will be held may be formed to sharp angles as shown in FIG. 28C, flat as shown in FIG. 28D, or curved as shown in FIG. 28E.

By the spin table 11 of this configuration, as shown in FIG. 28B, a large number of clamping grooves 115 and clamping holes 112 are formed, so the wafer W can be effectively held by suction.

### 23rd Embodiment

The present embodiment shows a specific type of spin table used for the embodiments of the present invention.

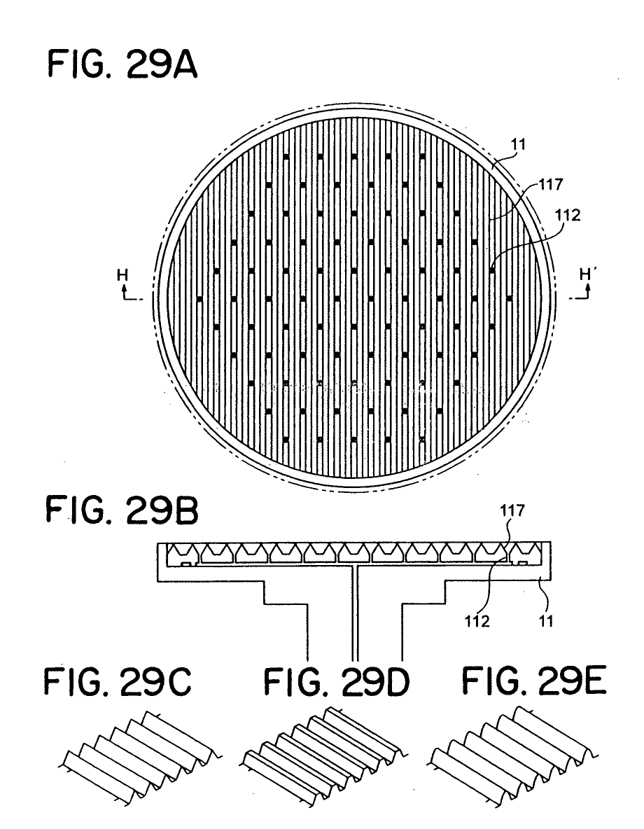

FIG. 29A is a plan view of a spin table used for the electroless plating apparatus according to the present embodiment, while FIG. 29B is a sectional view along the line H-H= of FIG. 29A.

As shown in FIG. 29A and FIG. 29B, in the spin table 11 used for the electroless plating apparatus according to the present embodiment, a large number of stripe-like clamping grooves 117 are formed large in opening area in the wafer direction. At the bottom surfaces of the clamping grooves 117 are formed clamping holes 112 in a manner similar to the 17th embodiment (see FIG. 23A). While not shown, it is also possible to form a gas blowing groove and gas blowing holes at the outer periphery of the spin table 11.

Note that the projections of the clamping grooves 117 by which the wafer W will be held may be formed to sharp angles as shown in FIG. 29C, flat as shown in FIG. 29D, or curved as shown in FIG. 29E.

By the spin table 11 of this configuration, as shown in FIG. 29B, a large number of clamping grooves 117 and clamping holes 112 are formed, so the wafer W can be effectively held by suction.

### 24th Embodiment

The present embodiment shows a specific type of spin table used for the embodiments of the present invention.

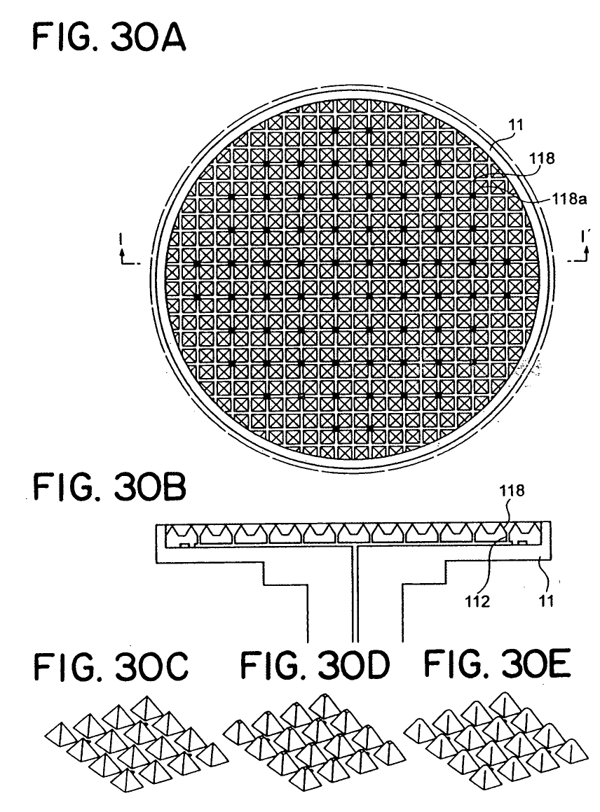

FIG. 30A is a plan view of a spin table used for the electroless plating apparatus according to the present embodiment, while FIG. 30B is a sectional view along the line I-I= of FIG. 30A.

As shown in FIG. 30A and FIG. 30B, in the spin table 11 used for the electroless plating apparatus according to the present embodiment, a large number of lattice-like clamping grooves 118 are formed large in opening area in the wafer direction. At the bottom surfaces of the clamping grooves 118 are formed clamping holes 112 in a manner similar to the 19th embodiment (see FIG. 25).

Since the clamping grooves 118 are formed in a lattice, the parts other than the grooves comprise repeatedly formed four-cornered pyramid shaped projecting parts 118a. While not shown, it is also possible to form a gas blowing groove and gas blowing holes at the outer periphery of the spin table 11.

Note that the front ends of the projecting parts 118a by which the wafer W will be held may be formed to sharp angles as shown in FIG. 30C, flat as shown in FIG. 30D, or curved as shown in FIG. 30E.

By the spin table 11 of this configuration, as shown in FIG. 30B, a large number of clamping grooves 118 and clamping holes. 112 are formed, so the wafer W can be effectively held by suction.

### 25th Embodiment

This embodiment shows a specific type of a spin table used in the embodiments of the present invention.

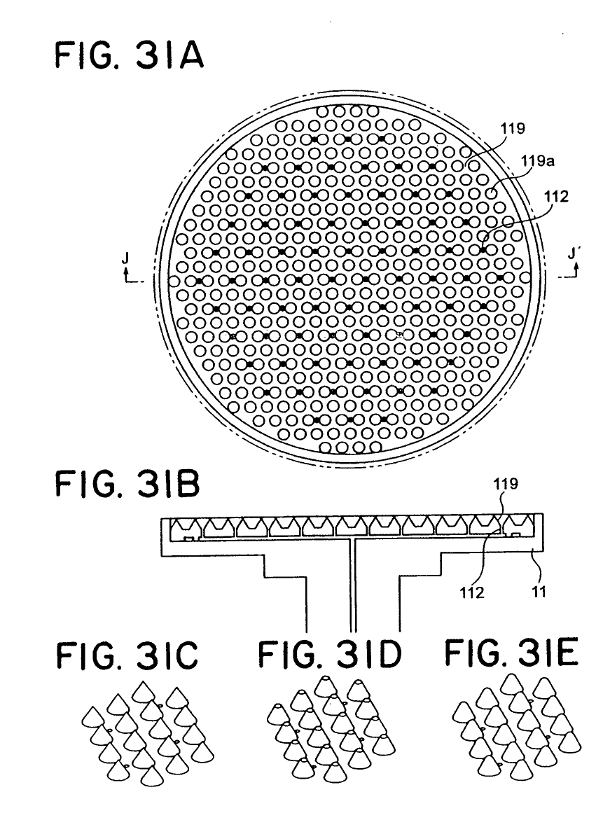

FIG. 31A is a plan view of a spin table used for the electroless plating apparatus according to the present embodiment, while FIG. 31B is a sectional view along the line J-J= of FIG. 31A.

As shown in FIG. 31A and FIG. 31B, in the spin table 11 used for the electroless plating apparatus according to the present embodiment, the clamping grooves 119 are formed so that a large number of conical shaped projecting parts 119 are repeatedly formed. At the bottom surfaces of the clamping grooves 119 are formed clamping holes 112 in a manner similar to the 17th embodiment (see FIG. 23A). While not shown, it is also possible to form a gas blowing groove and gas blowing holes at the outer periphery of the spin table 11.

Note that the front ends of the projecting parts 119a by which the wafer W will be held may be formed to sharp angles as shown in FIG. 31C, flat as shown in FIG. 31D, or curved as shown in FIG. 31E.

By the spin table 11 of this configuration, as shown in FIG. 31B, a large number of clamping grooves 119 and clamping holes 112 are formed, so the wafer W can be effectively held by suction.

The electroless plating apparatus and method of the present invention are not limited to the explanations of the above embodiments.

As the semiconductor chip formed with the conductive film by the present invention, an MOS transistor-type semiconductor chip, bipolar-type semiconductor chip, BiCMOS-type semiconductor chip, logic and memory carrying semiconductor chip, or any other semiconductor chip having contact holes, via holes, and other connection holes and groove interconnects can be used.

For example, the electroless plating apparatus of the present invention is not limited to electroless plating of cobalt for a barrier metal or electroless plating of copper for interconnects. It can also be applied to electroless plating of another metal.

Further, the electroless plating method of the present invention can be applied to a damascene process (groove interconnect forming process) or dual damascene process (process for simultaneously forming groove interconnects and contacts). Further, it can also be applied to the process of formation of only contacts.

Further, the present invention is not limited to micro interconnects of a semiconductor wafer and can also be used for plating of other metals and plating of printed circuit boards etc.

In addition, various changes can be made within the scope of the gist of the present invention.

### INDUSTRIAL APPLICABILITY

The electroless plating apparatus and method of the present invention can be applied to the formation of a conductive film in contact holes, via holes, and other connection holes or interconnect grooves in an MOS transistor-type semiconductor chip, bipolar-type semiconductor chip, BiCMOS-type semiconductor chip, logic and memory carrying semiconductor chip, etc. Further, the invention may also be applied to the plating of a printed circuit board etc. in addition to the micro interconnects of a semiconductor chip.

1. An electroless plating apparatus for electroless plating of a target surface in an atmosphere of a predetermined gas to form a conductive film,
said electroless plating apparatus having:
a plating tank set so that said target surface of a target object is close to its inside surface and isolating said target surface from an outside atmosphere and
a plating solution feeding means for feeding said plating solution to said target surface so as to ease impact of the plating solution to said target surface of said target object.

2. An electroless plating apparatus as set forth in claim 1, further having an agitating means for agitating said plating solution in said plating tank.

3. An electroless plating apparatus as set forth in claim 2, wherein said plating solution feeding means feeds said plating solution to a top surface of said agitating means and feeds said plating solution through said agitating means to said target surface.

4. An electroless plating apparatus as set forth in claim 3, wherein said agitating means can rotate and the top surface thereof has an inclined shape from a center of rotation to an outside.

5. An electroless plating apparatus as set forth in claim 2, wherein:
said agitating means has:
a holding unit for receiving said plating solution fed from said plating solution feeding means and
a feed hole formed at a bottom surface of said holding unit, and
said plating solution feeding means feeds said plating solution to said holding unit of said agitating means and feeds said plating solution to said target surface through said feed hole.

6. An electroless plating apparatus as set forth in claim 1, wherein:
said plating tank has a side wall surface formed with a spiral-shaped guide groove to said target object, and
said plating solution feeding means feeds said plating solution to said guide groove in said side wall surface of said plating tank.

7. An electroless plating apparatus as set forth in claim 6, wherein said spiral-shaped guide groove is formed so that a distance from a spiral axis becomes smaller the closer to said target object.

8. An electroless plating apparatus as set forth in claim 1, wherein:
said plating tank has a side wall surface formed with a conical inclined surface, and
said plating solution feeding means feeds said plating solution to said side wall surface of said plating tank.

9. An electroless plating apparatus as set forth in claim 1, further having a holding member provided with a holding surface for holding said target object and able to move said target object in a direction to face said plating tank.

10. An electroless plating apparatus as set forth in claim 9, wherein said holding member has a clamping hole for holding by suction clamping said target object to said holding surface.

11. An electroless plating apparatus as set forth in claim 9, wherein said holding member has a groove formed with a blowing hole for blowing an inert gas or nitrogen-containing gas at an outer periphery of said holding surface.

12. An electroless plating apparatus as set forth in claim 11, wherein:
said holding member has a holding surface of a size substantially equal to said target object, and
said plating tank is set at an edge of said target surface in said target object via a seal member and isolates said target surface from the outside atmosphere.

13. An electroless plating apparatus as set forth in claim 11, wherein:
said holding member has a holding surface larger than said target object, and
said plating tank is set on said holding member via a seal member and isolates said target surface from the outside atmosphere.

14. An electroless plating apparatus as set forth in claim 9, wherein said holding member has a heating means for heating said target object.

15. An electroless plating apparatus as set forth in claim 1, wherein said plating tank has a heating means for heating said predetermined gas and said plating solution in said plating tank.

16. An electroless plating apparatus as set forth in claim 1, wherein said plating solution feeding means feeds said plating solution containing a first metal material for supplying a main ingredient of said conductive film, a complexing agent, a reducing agent, and a pH adjuster and adjusted in pH to a range from neutral to alkaline.

17. An electroless plating apparatus as set forth in claim 16, wherein said plating solution feeding means feeds said plating solution further containing a second metal material for supplying an ingredient for enhancing a barrier property of said conductive film.

18. An electroless plating apparatus as set forth in claim 16, wherein said plating solution feeding means feeds said plating solution further containing a first complexing agent of an amphoteric ion type and a second complexing agent for accelerating a plating reaction.

19. An electroless plating apparatus as set forth in claim 16, further having:
a plating solution tank for holding said plating solution fed to said plating tank and
a pH adjusting means for adjusting a pH of said plating solution in said plating solution tank.

20. An electroless plating apparatus as set forth in claim 1, further having a gas feeding means for feeding an inert gas or nitrogen-containing gas as said predetermined gas to the inside said plating tank.

21. An electroless plating apparatus as set forth in claim 1, further having:
a plating chamber for holding said plating tank and
a gas feeding means for feeding an inert gas or nitrogen-containing gas as said predetermined gas to the inside of said plating chamber.

22. An electroless plating apparatus as set forth in claim 1, further having:
a plating chamber for holding said plating tank,
a standby chamber connected to said plating chamber for loading and unloading said target object, and
a gas feeding means for feeding an inert gas or nitrogen-containing gas as said predetermined gas to the inside of said plating chamber and said standby chamber.

23. An electroless plating apparatus for electroless plating of a target surface to form a conductive film,
said electroless plating apparatus having:
a plating tank for holding a plating solution under an atmosphere of a predetermined gas and
a holding member provided with a holding surface for holding said target object, having a clamping hole for suction clamping said target object to said holding surface, and having a groove formed with a blowing hole for blowing out said predetermined gas at an outer periphery of said holding surface and
dipping said target object held by said holding member in said plating tank for electroless plating.

24. An electroless plating apparatus as set forth in claim 23, wherein said predetermined gas is an inert gas or nitrogen-containing gas.

25. An electroless plating apparatus as set forth in claim 23, wherein said holding member dips said target object so that said target surface of said target object is close to an inside surface of said plating tank.

26. An electroless plating apparatus as set forth in claim 25, wherein said holding member dips said target object in a state with said target surface inclined to a predetermined angle with respect to a surface of said plating solution.

27. An electroless plating apparatus as set forth in claim 23, further having a gas removing means for removing a reaction gas accompanied with electroless plating of said target surface.

28. An electroless plating apparatus as set forth in claim 27, wherein said gas removing means generates an ultrasonic wave with respect to said target surface of said target object dipped in said plating tank.

29. An electroless plating apparatus as set forth in claim 27, wherein said gas removing means discharges one of an inert gas, nitrogen-containing gas, or said plating solution to said target surface of said target object dipped in said plating tank.

30. An electroless plating apparatus as set forth in claim 23, wherein said holding member can rotate.

31. (Deleted)

32. (Deleted)

33. (Deleted)

34. (Deleted)

35. (Deleted)

36. An electroless plating method for electroless plating of a target surface in an atmosphere of a predetermined gas to form a conductive film, said electroless plating method comprising:
setting a plating tank so that said target surface of a target object is isolated from an outside atmosphere and making the inside of said plating tank an atmosphere of a predetermined gas and
feeding a plating solution to said target surface so as to ease impact of the plating solution to said target surface of said target object and performing electroless plating.

37. An electroless plating method as set forth in claim 36, further comprising performing said electroless plating while agitating said plating solution in said plating tank by an agitating means.

38. An electroless plating method as set forth in claim 37, further comprising feeding said plating solution to a top surface of said agitating means and feeding said plating solution through said agitating means to said target surface.

39. An electroless plating method as set forth in claim 36, further comprising feeding said plating solution to a side wall surface of said plating tank and feeding said plating solution to said target surface along said side wall surface.

40. An electroless plating method as set forth in claim 36, further comprising feeding said plating solution containing a first metal material for supplying a main ingredient of said conductive film, a complexing agent, a reducing agent, and a pH adjuster and adjusted in pH to a range from neutral to alkaline.

41. An electroless plating method as set forth in claim 40, further comprising feeding said plating solution further containing a second metal material for supplying an ingredient for enhancing a barrier property of said conductive film.

42. An electroless plating method as set forth in claim 40, further comprising feeding said plating solution further containing a first completing agent of an amphoteric ion type and a second completing agent for accelerating a plating reaction.

43. An electroless plating method as set forth in claim 36, further comprising using an inert gas or nitrogen-containing gas as said predetermined gas.

44. An electroless plating method as set forth in claim 36, further comprising:
having said plating tank set in a plating chamber and
performing said electroless plating in said plating chamber filled with an inert gas or nitrogen-containing gas as said predetermined gas.

45. An electroless plating method dipping a target object in a plating tank holding a plating solution for electroless plating of a target surface of said target object to form a conductive film, said electroless plating method comprising:
placing said target object on a holding surface of a holding member, blowing a predetermined gas from an outer periphery of said holding surface, and in that state holding said target object by suction clamping at said holding surface, and
dipping said target object held by said holding member in said plating tank set to an atmosphere of a predetermined gas so that said target surface is close to an inside surface of said plating tank.

46. An electroless plating method as set forth in claim 45, further comprising dipping said target object in a state with said target surface inclined to a predetermined angle with respect to a surface of said plating solution when dipping said target object in said plating tank.

47. An electroless plating method as set forth in claim 45, further comprising a gas removing step of removing a reaction gas accompanied with electroless plating of said target surface after dipping it in said plating tank.

48. An electroless plating method as set forth in claim 47, wherein said gas removing step generates an ultrasonic wave with respect to said target surface dipped in said plating tank.

49. An electroless plating method as set forth in claim 47, wherein said gas removing step discharges one of an inert gas, nitrogen-containing gas, or said plating solution to said target surface dipped in said plating tank.

50. An electroless plating method as set forth in claim 47, wherein said gas removing step is performed after the elapse of an initial reaction time of electroless plating after dipping said target object in said plating tank.
